(19) United States
(12) Patent Application Publication
(10) Pub. No.: US 2008/0185629 A1
(43) Pub. Date: Aug. 7, 2008

(54) Semiconductor device having variable operating information

(75) Inventors: Takashi Nakano, Nukata-gun (JP); Mitsuhiro Kanayama, Takahama-city (JP); Tooru Itabashi, Anjo-city (JP); Shigeki Takahashi, Okazaki-city (JP); Nozomu Akagi, Nukata-gun (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/717,166

(22) Filed: Mar. 13, 2007

(30) Foreign Application Priority Data
Feb. 1, 2007 (JP) 2007-23324

(51) Int. Cl. H01L 29/788

(52) U.S. Cl. 257/316; 257/E29.3

(57) ABSTRACT

A semiconductor device includes: a semiconductor substrate; multiple MOS type first transistors coupled in parallel with a current path; and a nonvolatile memory for memorizing operating information. Each transistor includes first and second electrodes and a gate electrode for controlling current flowing therebetween. Based on the operating information, each first transistor is selectively set to an active state. When the transistors provide a single transistor, an effective channel width of the single transistor is variable in accordance with the number of the first transistors under the active state.

### CROSS REFERENCE TO RELATED APPLICATIONS

This application is based on Japanese Patent Applications No. 2006-27092 filed on Feb. 3, 2006, and No. 2007-23324 filed on Feb. 1, 2007, the disclosures of which are incorporated herein by reference.

### FIELD OF THE INVENTION

The present invention relates to a semiconductor device having variable operating information.

### BACKGROUND OF THE INVENTION

Heretofore, as a semiconductor device of this type, there has been known a semiconductor device wherein, as the partial side sectional structure thereof is exemplified in FIG. 26, a lateral MOS (LDMOS: Lateral Diffused Metal Oxide Semiconductor) is packaged on a semiconductor substrate. Now, the semiconduct or device will be outlined with reference to FIG. 26.

As shown in FIG. 26, the semiconductor device is configured having a plurality of impurity regions which are formed in such a manner that the semiconductor substrate 100 is doped with impurities of suitable conductive types. That is, the semiconductor device is basically configured having a drain region 101 which is made of a diffusion layer of N-type constructing the major part of the semiconductor substrate 100, and a channel region 102 which is made of a diffusion layer of P-type (P well) formed in the vicinity of the upper surface of the semiconductor substrate 100.

Here, the channel region 102 is formed in a manner to surround a substrate contact portion 103 which is made of a diffusion layer of P-type (P⁺) formed at a concentration higher than that of the channel region 102, and a source region 104 which is made of a diffusion layer of N-type (N⁺) formed at a concentration higher than that of the drain region 101. Besides, the drain region 101 is formed with a drain contact portion 105 which is made of a diffusion layer (N⁺) at a concentration higher than that of this drain region 101.

On the other hand, a field oxide film (LOCOS oxide film) 106 which has a LOCOS structure is formed in the vicinity of the channel region 102 of the substrate 100 so as to isolate the channel region 102 and the drain contact portion 105 from each other. In addition, a gate electrode 107 made of, for example, polycrystal silicon is formed on the channel region 102 through a gate insulating film GI made of, for example, silicon oxide, and so as to partly overlap the LOCOS oxide film 106.

Incidentally, as shown in FIG. 26, the gate electrode 107 is usually covered with an insulating film ILD made of, for example, BPSG (Boron Phosphorous Silicate Glass), thereby to be insulated from the surroundings, and it is electrically connected to an operating voltage input terminal Vin through a contact hole (not shown) formed in the insulating film ILD. Likewise, an insulating film ILD is formed also on the substrate contact portion 103 and the source region 104, and the substrate contact portion 103 and the source region 104 is held at, for example, a ground (GND) potential through contact holes (not shown) formed in the insulating film ILD. Further, an insulating film ILD is formed also on the drain contact portion 105, and the drain contact portion 105 is electrically connected to, for example, a circuit power source Vc through a contact hole (not shown) formed in the insulating film ILD. By the way, in this case, a load which is to be operated by the semiconductor device (transistor) is usually connected between the drain contact portion 105 and the circuit power source Vc.

In the semiconductor device thus configured, an operating voltage is applied from the operating voltage input terminal Vin to the gate electrode 107, whereby an inversion layer is formed between the drain region 101 and the source region 104, more exactly, at the part of the channel region 102 directly under the gate electrode 107, and current flows within the inversion layer. In addition, the operating voltage which is applied from the operating voltage input terminal Vin to the gate electrode 107 is regulated, whereby the quantity of the current which flows between the drain region 101 and the source region 104 can be made variable.

Meanwhile, in manufacturing such a semiconductor device, required values for an on-resistance, a switching time, etc. which correspond to the quantity of the current flowing through the channel region 102 are usually found in consideration of, for example, the supposed magnitude of the load to-be-operated which is connected to the drain region 101 (exactly, the drain contact portion 105). In addition, the total layout including the sizes and impurity concentrations of the individual impurity regions, etc. as the semiconductor device is determined so as to satisfy the required values. However, even when the semiconductor device has been successfully manufactured under the layout thus determined, the readjustments of the on-resistance, the switching time, etc. are sometimes needed for such a reason as the alteration of the load to-be-operated which is connected, or the problem of heat generation or the like. Since, however, a degree of freedom for the alterations of such required values is very low in the prior-art semiconductor device configured as the lateral MOS, design alterations such as changing a layout size so as to suit the required values have been eventually inevitable. That is, the semiconductor device itself is remade from the beginning in correspondence with the alteration of the load to-be-operated which is connected, or the like.

Incidentally, such circumstances are not restricted to the semiconductor device having the lateral MOS structure, but they are substantially common to a semiconductor device which is configured as a transistor having a general MOS structure.

That is, in the semiconductor devices, it is requested to cope with the adjustments and alterations of the various required values at a high degree of freedom even in a case where the readjustments of the required values are needed due to, for example, the alteration of the load.

### SUMMARY OF THE INVENTION

In view of the above-described problem, it is an object of the present disclosure to provide a semiconductor device having variable operating information.

According to a first aspect of the present disclosure, a semiconductor device includes: a semiconductor substrate; a plurality of MOS type first transistors disposed on the semiconductor substrate; and a nonvolatile memory for memorizing an operating information of each first transistor. The plurality of first transistors is electrically coupled in parallel with a current path. Each first transistor includes a first electrode and a second electrode disposed on the current path, and further includes a gate electrode for controlling current flowing between the first and second electrodes based on an applied voltage. The operating information of each first transistor is variably set. Each first transistor is selectively set to an active state based on the operating information. When the plurality of first transistors provides a single transistor, an effective channel width of the single transistor is variable in accordance with the number of the first transistors under the active state.

In the semiconductor device having the above structure, assuming that separated multiple transistors provide a single transistor, an on-state resistance and/or a switching time are adjustable by controlling the operating information variably set in the nonvolatile memory even after the semiconductor device is manufactured. Accordingly, even when various requirements are necessary to adjust again in accordance with change of a load, it is possible to deal with the change and adjustment of requirements with high degree of freedom.

According to a second aspect of the present disclosure, a semiconductor device includes: a plurality of MOS type first transistors. The plurality of first transistors is electrically coupled in parallel with a current path. Each first transistor includes a first electrode and a second electrode disposed on the current path, and further includes a gate electrode for controlling current flowing between the first and second electrodes based on an applied voltage. The gate electrode of at least one of first transistors includes a first gate electrode and a second gate electrode. The first gate electrode is disposed on the first electrode and covers a channel region. The second gate electrode is disposed on the channel region and covers the second electrode.

In the above semiconductor device, the first gate electrode and the second gate electrode have channel layers, respectively. Accordingly, a voltage applied to the first gate electrode is independently controlled from a voltage applied to the second gate electrode so that much complicated control can be performed.

According to a third aspect of the present disclosure, a semiconductor device includes: a plurality of MOS type first transistors. The plurality of first transistors is electrically coupled in parallel with a current path. Each first transistor includes a first electrode and a second electrode disposed on the current path, and further includes a gate electrode for controlling current flowing between the first and second electrodes based on an applied voltage. The gate electrode of at least one of first transistors includes a first control electrode and a second control electrode. The first control electrode covers a channel region disposed from the first electrode to the second electrode. The first control electrode opens and closes between the first electrode and the second electrode. The second control electrode covers the second electrode.

In the above device, the first control electrode functioning as a gate electrode turns on and off (i.e., opens and closes). The charge accumulation layer provided by the second control electrode controls a current flowing amount, i.e., a resistance. Accordingly, an on-state resistance is much accurately controlled, compared with a case where a transistor is simply controlled to turn on and off. Further, only the first control electrode substantially functions as the gate electrode. Thus, a facing area between the first control electrode and the second electrode becomes small, so that a parasitic capacitance is reduced.

### BRIEF DESCRIPTION OF THE DRAWINGS

The above and other objects, features and advantages of the present invention will become more apparent from the following detailed description made with reference to the accompanying drawings. In the drawings:

FIG. 1 is a circuit diagram showing an example of a general equivalent circuit which centers around a semiconductor substrate and which includes a load to-be-operated, in relation to a first embodiment of a semiconductor device;

FIG. 2 is a plan view schematically showing a planar structure in relation to an LDMOS region which is formed in the semiconductor substrate of the first embodiment;

FIG. 3 is a circuit diagram showing an example of a general equivalent circuit which centers around a semiconductor substrate and which includes a load to-be-operated, in relation to a second embodiment of a semiconductor device;

FIG. 4 is a plan view schematically showing a planar structure in relation to an LDMOS region which is formed in the semiconductor substrate of the second embodiment;

FIG. 5 is a circuit diagram showing an example of a general equivalent circuit which centers around a semiconductor substrate and which includes a load to-be-operated, in relation to a third embodiment of a semiconductor device;

FIG. 6 is a plan view schematically showing a planar structure in relation to an LDMOS region which is formed in the semiconductor substrate of the third embodiment;

FIG. 7 is a circuit diagram showing an example of a general equivalent circuit which centers around a semiconductor substrate and which includes a load to-be-operated, in relation to a fourth embodiment of a semiconductor device;

FIG. 8 is a plan view schematically showing a planar structure in relation to an LDMOS region which is formed in the semiconductor substrate of the fourth embodiment;

FIG. 9 is a side sectional view showing an example of a sectional structure in relation to a fifth embodiment of a semiconductor device;

FIG. 10 is a side sectional view showing an example of a sectional structure in relation to a modification to the semiconductor device of the fifth embodiment;

FIG. 11 is a side sectional view showing an example of a sectional structure in relation to a sixth embodiment of a semiconductor device;

FIG. 12 is a side sectional view showing an example of a sectional structure in relation to a modification to the semiconductor device of the sixth embodiment;

FIG. 13 is a side sectional view showing an example of a sectional structure in relation to a modification to the semiconductor device of the sixth embodiment;

FIG. 14 is a side sectional view showing an example of a sectional structure in relation to a modification to the semiconductor device of the sixth embodiment;

FIG. 15A is a side sectional view showing an example of a sectional structure in relation to a seventh embodiment of a semiconductor device, while FIG. 15B is an equivalent circuit diagram;

FIG. 16 is a side sectional view showing an example of a sectional structure in relation to a modification to the semiconductor device of the seventh embodiment;

FIG. 17 is a side sectional view showing an example of a sectional structure in relation to a modification to the semiconductor device of the seventh embodiment;

FIG. 18 is a side sectional view showing an example of a sectional structure in relation to a modification to the semiconductor device of the seventh embodiment;

FIG. 19 is a plan view schematically showing an example of a planar structure in relation to a modification to each of the third to sixth embodiments of the semiconductor devices;

FIG. 20 is a plan view schematically showing an example of a planar structure in relation to another modification to each of the third to sixth embodiments of the semiconductor devices;

FIG. 21 is a side sectional view showing an example of a sectional structure in relation to a case where each of the first to sixth embodiments of the semiconductor devices is applied to a transistor having a VDMOS structure;

FIG. 22 is a side sectional view showing another example of a sectional structure in relation to a case where each of the first to sixth embodiments of the semiconductor devices is applied to a transistor having a VDMOS structure;

FIG. 23 is a side sectional view showing an example of a sectional structure in relation to a case where each of the first to sixth embodiments of the semiconductor devices is applied to a transistor having an IGBT structure;

FIG. 24 is a side sectional view showing another example of a sectional structure in relation to a case where each of the first to sixth embodiments of the semiconductor devices is applied to a transistor having an IGBT structure;

FIGS. 25A to 25C are side sectional views each showing an example of another element which is formed in a semiconductor device; and

FIG. 26 is a side sectional view showing the sectional structure of a prior art semiconductor device.

### DETAILED DESCRIPTION OF THE PREFERRED EMBODIMENTS

### First Embodiment

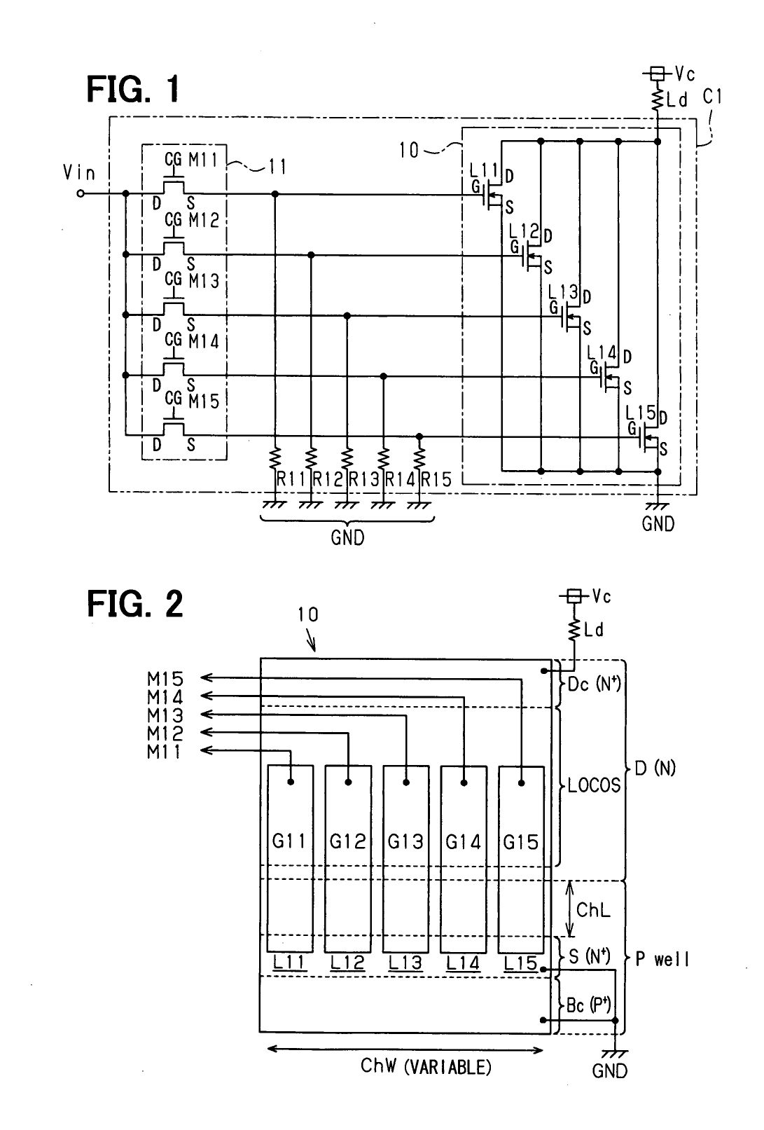

Now, a first embodiment of a semiconductor device according to this invention will be described with reference to FIGS. 1 and 2.

In this embodiment, a configuration to be stated below is basically adopted as will be detailed later. A transistor having an LDMOS structure which includes drain and source electrodes that are connected so as to intervene in the path of current, and a gate electrode that controls the current to flow between the drain and source electrodes in accordance with an applied voltage is arrayed and formed in a semiconductor substrate in a manner to be divided into a plurality of transistors which are electrically connected in parallel with the path of the current. In addition, operating information which indicates whether or not operating voltages are to be applied to the respective gate electrodes of the plurality of transistors constituting the LDMOS region can be variably set in a plurality of memory cells which constitute a nonvolatile memory region in the identical semiconductor substrate, and the plurality of transistors are selectively activated on the basis of the set operating information. Thus, the required values of an on-resistance, a switching time, etc. at the time when the plurality of transistors are regarded as a single transistor are made variable, and even in a case, for example, where the readjustments of the required values are needed due to the alteration of a load, the adjustments and alterations of the required values can be coped with at a high degree of freedom.

FIG. 1 shows a general equivalent circuit centering around the semiconductor substrate on which such a semiconductor device is packaged, and including the load to-be-operated, while FIG. 2 schematically shows a planar structure in relation to the LDMOS region which is formed in the semiconductor substrate.

First, as shown in FIG. 1, the semiconductor substrate C1 on which the semiconductor device of this embodiment is packaged is disposed in a manner to intervene in that path of current which extends from a circuit power source Vc to the ground (GND) through the load to-be-operated Ld. Here, the load to-be-operated Ld is a load which is constructed of, for example, the resistor of a heater or the like, or the coil (inductance) of a motor or the like. In addition, the semiconductor substrate C1 is basically configured including the LDMOS region 10 which is a transistor region having the LDMOS structure, and a nonvolatile memory region 11 which is a region where the operating information is variably set.

In the LDMOS region 10 of them, as stated above, the transistor having the LDMOS structure is arrayed and formed in the semiconductor substrate C1 in a manner to be divided into, for example, five transistors L11-L15 which are electrically connected in parallel with the path of the current. Each of the transistors L11-L15 has a structure similar to the LDMOS structure exemplified in FIG. 26 before, the drain electrodes (first electrodes) D and source electrodes (second electrodes) S are respectively connected to the path of the current, and the gate electrodes G each of which controls current to flow between the corresponding drain electrode D and source electrode S are connected to respective memory cells which constitute the nonvolatile memory region 11.

Besides, the five memory cells M11-M15 in the same number as that of the transistors L11-L15 are formed in the nonvolatile memory region 11 which is formed of an electrically rewritable nonvolatile memory (for example, EPROM). Also each of the memory cells M11-M15 has a MOS structure basically, and as shown in FIG. 1, it includes a drain electrode D and a source electrode S, and a control gate electrode CG which controls whether or not current is to flow between the drain electrode D and the source electrode S, on the basis of the voltage applied in accordance with the operating information. In addition, the respective drain electrodes D of the memory cells M11-M15 are electrically connected in parallel with an operating voltage input terminal Vin to which an operating voltage formed of a constant voltage or a rectangular wave voltage is inputted, and the respective source electrodes S of the memory cells M11-M15 are connected to the corresponding gate electrodes G of the transistors L11-L15. That is, the memory cells M11-M15 constituting the nonvolatile memory region 11 function as switching elements for performing switching (on/off), in a manner to intervene in the application lines of the operating voltages to the respective gate electrodes G of the transistors L11-L15 constituting the LDMOS region 10.

Incidentally, the control gate electrodes CG of the memory cells M11-M15 are connected to a voltage control circuit (not shown), and predetermined voltages which correspond to the logic levels of rewritable information items of 5 bits constituting the operating information of the transistors L11-L15 are applied to the respective control gate electrodes CG through the voltage control circuit. Concretely, a voltage at a magnitude which brings the corresponding memory cell into an on-state is applied to the control gate electrode CG of the memory cell which corresponds to the bit that lies at, for example, a logic H (high) level among the bits constituting the operating information. On the other hand, a voltage at a magnitude which brings the corresponding memory cell into an off-state is applied to the control gate electrode CG of the memory cell which corresponds to the bit that lies at, for example, a logic L (low) level among the bits constituting the operating information. Thus, the on/off-states of the lines which couple the source electrodes S of the memory cells M11-M15 and the gate electrodes G of the transistors L11-L15, namely, the application lines of the operating voltages are respectively changed-over.

Meanwhile, as shown in FIG. 1, pull-down resistors R11-R15 are respectively connected to the application lines of the operating voltages, and they are grounded (GND) at their ends remote from the application lines. In these lines, therefore, the voltage division values (divided voltages) of the operating voltages based on the on-resistances of the memory cells M11-M15 and the corresponding pull-down resistors R11-R15 are applied to the corresponding gate electrodes G among the transistors L11-L15, and the transistors to which the divided voltages are applied are selectively activated. To the contrary, the lines which correspond to the cells under the off-states, among the memory cells M11-M15 are fixed to the ground (GND) potential by the corresponding pull-down resistors. That is, among the transistors L11-L15, the transistors whose gate electrodes G are connected to the lines have their gate potentials fixed to the ground (GND) potential, and channels are not formed therein.

Here, in this embodiment, as the planar structure of the transistors L11-L15 constituting the LDMOS region 10 is shown in FIG. 2, the individual drain electrodes (regions) D are, in actuality, electrically connected with one another through a drain contact portion Dc which consists of a diffusion layer of N-type and a diffusion layer of high concentration (N⁺) that are formed within the semiconductor substrate C1. In addition, the end of the load to-be-operated Ld connected to the circuit power source Vc as is remote from this circuit power source is connected to the drain contact portion Dc through a suitable wiring. Likewise, the individual source electrodes (regions) S of the transistors L11-L15 are, in actuality, electrically connected with one another through a diffusion layer of high concentration (N⁺) which is disposed in a P well. Incidentally, the source electrodes (regions) S are held at the ground (GND) potential through a suitable wiring, together with a substrate contact portion Bc which is similarly formed as a diffusion layer of high concentration (P⁺) in the P well. In this way, the transistors L11-L15 constituting the LDMOS region 10 are respectively connected so as to intervene in the current path of the load to-be-operated Ld.

On the other hand, as shown in FIG. 2, only the gate electrodes G of the transistors L11-L15 are formed in a manner to be electrically separated from one another in the LDMOS region 10, and the respective gate electrodes G are electrically connected through suitable wirings to the source electrodes S (FIG. 1) of the memory cells M11-M15 constituting the above nonvolatile memory region 11. In addition, the operating voltages are selectively applied to the gate electrodes G as stated above, whereby channel layers (inversion layers) of channel length ChL are formed at parts directly under those gate electrodes of the gate electrodes G11-G15 to which the operating voltages are applied, and those transistors of the transistors L11-L15 which are formed with the channel layers are selectively activated. That is, currents flow through the formed channel layers. In other words, an effective channel width ChW at the time when the transistors L11-L15 are regarded as the single transistor becomes variable within the LDMOS region 10 in accordance with the number of the activated transistors.

Next, there will be described a method for adjusting the effective channel width ChW at the time when the LDMOS region 10 is regarded as the single transistor, in the semiconductor device configured as stated above. Incidentally, the adjustment can be executed at will even after the manufacture of the semiconductor device.

In making the adjustment, the operating information which indicates whether or not the operating voltages are to be applied to the gate electrodes G (G11-G15) of the transistors L11-L15 (FIG. 1) is first set in the nonvolatile memory region 11. The setting aspect of the operating information can be freely altered through a well-known memory manipulation. In this way, the predetermined voltages which correspond to the logic levels of the respective bits constituting the operating information are applied to the control gate electrodes CG of the memory cells M11-M15, thereby to selectively bring these memory cells into the on-states. Thus, currents flow from the operating voltage input terminal Vin shown in FIG. 1, between the drain electrodes D and the source electrodes S of the memory cells (switching elements) brought into the on-states on the basis of the operating voltages applied to the drain electrodes D of the memory cells M11-M15, and through the pull-down resistors connected to the lines succeeding to these memory cells, and they lead to the ground (GND), respectively. In the lines through which the currents have flowed in this way, the divided voltages of the operating voltages based on the on-resistances of the memory cells under the on-states and the pull-down resistors corresponding thereto are applied to the gate electrodes G of the corresponding transistors among the transistors L11-L15, and the transistors to which the divided voltages have been applied are activated. That is, current fed from the circuit power source Vc to the load to-be-operated Ld flows through only the activated transistors, and the effective channel width ChW at the time when the transistors L11-L15 are regarded as the single transistor is made variable within the semiconductor substrate C1, in accordance with the number of the activated transistors.

As described above, in accordance with the semiconductor device according to the first embodiment, advantages to be listed below are obtained.

(1) The operating information which indicates whether or not the operating voltages are to be applied to the gate electrodes G (G11-G15) of the transistors L11-L15 constituting the LDMOS region 10 is variably set in the nonvolatile memory region 11, and the transistors L11-L15 are selectively activated on the basis of the operating information. Thus, even after the manufacture of the semiconductor device, the required values of the on-resistance, the switching time, etc. at the time when the transistors L11-L15 are regarded as the single transistor can be adjusted through the application aspect of the operating voltages to the gate electrodes G (G11-G15). Accordingly, even in the case, for example, where the readjustments of the required values are needed due to the alteration of the load, or the like, the adjustments and alterations of the required values can be coped with at a high degree of freedom.

(2) The LDMOS region 10 and the nonvolatile memory region 11 are formed on the identical semiconductor substrate C1. Thus, reduction in size can be attained as the semiconductor device. Besides, as regards the transistors L11-L15 constituting the LDMOS region 10 and the memory cells M11-M15 constituting the nonvolatile memory region 11, many of semiconductor manufacturing processes are common, and hence, reduction in the manufacturing man-hour of the semiconductor device can be attained.

(3) The drain electrodes (regions) D and source electrodes (regions) S of the transistors L11-L15 are electrically connected through the diffusion layers, respectively. Thus, it is dispensed with to lay metallic wirings or the like which serve to electrically connect the transistors L11-L15 in parallel with the path of the current extending from the circuit power source Vc to the ground (GND), so that the simplification of the structure, as well as the simplification of the manufacturing process can be attained. Moreover, as compared with the case of laying the metallic wirings or the like, the embodiment sweeps off the apprehension of disconnection, etc., so that the semiconductor device of higher reliability can be realized.

### Second Embodiment

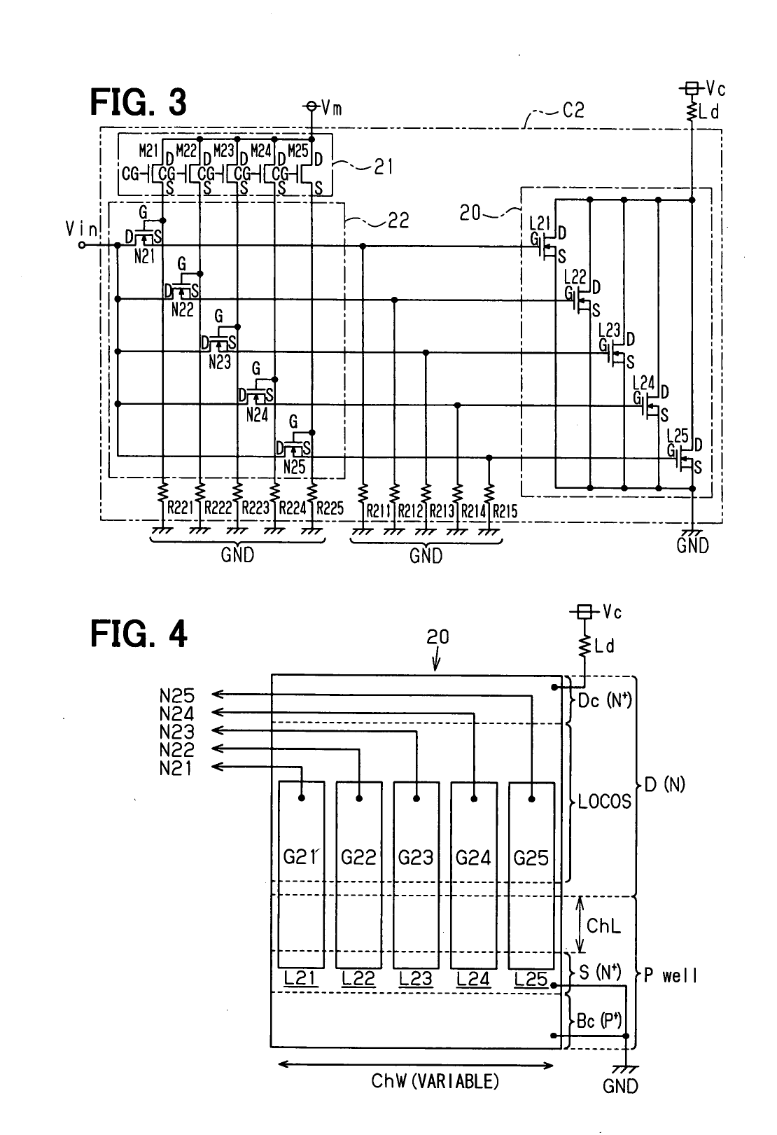

Next, a second embodiment of a semiconductor device according to this invention will be described with reference to FIGS. 3 and 4.

Also the semiconductor device of this embodiment has a configuration which basically conforms to the first embodiment shown in FIGS. 1 and 2 before, namely, a configuration in which operating information that indicates whether or not operating voltages are to be applied to the gate electrodes of a plurality of transistors constituting an LDMOS region can be variably set in a plurality of memory cells constituting a nonvolatile memory region within an identical semiconductor substrate. In this embodiment, however, a plurality of MOS transistors are respectively connected in a manner to intervene in the application lines of the operating voltages to the gate electrodes of the plurality of transistors mentioned above, and the plurality of transistors mentioned above are selectively activated through the operations of the plurality of MOS transistors on the basis of the operating information.

FIG. 3 shows a general equivalent circuit centering around the semiconductor substrate on which such a semiconductor device is packaged, and including a load to-be-operated, while FIG. 4 schematically shows a planar structure in relation to the LDMOS region which is formed in the semiconductor substrate.

First, as shown in FIG. 3, the semiconductor substrate C2 on which the semiconductor device of this embodiment is packaged is disposed in a manner to intervene in that path of current which extends from a circuit power source Vc to the ground (GND) through the load to-be-operated Ld, in the same manner as in the foregoing first embodiment. The semiconductor substrate C2 is basically configured including the LDMOS region 20 which is a transistor region having an LDMOS structure, the nonvolatile memory region 21 which is a region where the operating information is variably set, and an N-channel MOS region 22 which is connected in the manner to intervene in the application lines of the operating voltages.

In the LDMOS region 20 of them, in the same manner as in the foregoing first embodiment, the transistor having the LDMOS structure is arrayed and formed in the semiconductor substrate C2 in a manner to be divided into, for example, five transistors L21-L25 which are electrically connected in parallel with the path of the current. Each of the transistors L21-L25 has a structure conforming to the LDMOS structure exemplified in FIG. 26 before. Here, however, the drain electrodes D and source electrodes S of these transistors are respectively connected to the path of the current, and the gate electrodes G thereof, each of which controls current to flow between the corresponding drain electrode D and source electrode S, are connected to the respective MOS transistors which constitute the N-channel MOS region 22.

Besides, the five memory cells M21-M25 in the same number as that of the transistors L21-L25 are formed in the nonvolatile memory region 21 which is formed of an electrically rewritable nonvolatile memory (for example, EPROM), in the same manner as in the foregoing first embodiment. Also each of the memory cells M21-M25 has a MOS structure basically, and as shown in FIG. 3, it includes a drain electrode D and a source electrode S, and a control gate electrode CG which controls whether or not current is to flow between the drain electrode D and the source electrode S, on the basis of the voltage applied in accordance with the operating information. In addition, the respective drain electrodes D of the memory cells M21-M25 are electrically connected in parallel with a memory power source Vm to which a memory voltage formed of a constant voltage is applied, and the respective source electrodes S of the memory cells M21-M25 are connected to the corresponding MOS transistors which constitute the N-channel MOS region 22.

Incidentally, also the control gate electrodes CG of the memory cells M21-M25 are connected to a voltage control circuit (not shown) in the same manner as in the foregoing first embodiment. In addition, predetermined voltages which correspond to the logic levels of rewritable information items of 5 bits constituting the operating information of the transistors L21-L25 are applied to the respective control gate electrodes CG through the voltage control circuit. Concretely, a voltage at a magnitude which brings the corresponding memory cell into an on-state is applied to the control gate electrode CG of the memory cell which corresponds to the bit that lies at, for example, a logic H (high) level among the bits constituting the operating information. On the other hand, a voltage at a magnitude which brings the corresponding memory cell into an off-state is applied to the control gate electrode CG of the memory cell which corresponds to the bit that lies at, for example, a logic L (low) level among the bits constituting the operating information.

Besides, the five MOS transistors N21-N25 also in the same number as that of the transistors L21-L25 are formed in the N-channel MOS region 22. As shown in FIG. 3, the drain electrodes D of the MOS transistors N21-N25 are electrically connected in parallel with an operating voltage input terminal Vin being a terminal to which the operating voltages are inputted, while the source electrodes S of the MOS transistors N21-N25 are respectively connected to the transistors L21-L25 constituting the LDMOS region 20.

Meanwhile, as shown in FIG. 3, pull-down resistors R211-R215 are respectively connected to the application lines of the operating voltages to the gate electrodes G of the transistors L21-L25 constituting the LDMOS region 20, and they are grounded (GND) at their ends remote from the application lines. In these lines, therefore, the voltage division values (divided voltages) of the operating voltages based on the on-resistances of the MOS transistors N21-N25 and the corresponding pull-down resistors R211-R215 are applied to the corresponding gate electrodes G among the transistors L21-L25, and the transistors to which the divided voltages are applied are selectively activated. To the contrary, the lines which correspond to the cells under the off-states, among the MOS transistors N21-N25 are fixed to the ground (GND) potential by the corresponding pull-down resistors. That is, among the transistors L21-L25, the transistors whose gate electrodes G are connected to the lines have their gate potentials fixed to the ground (GND) potential, and channels are not formed therein.

Further, as shown in FIG. 3, pull-down resistors R221-R225 are respectively connected to the application lines of the memory voltages to the gate electrodes G of the MOS transistors N21-N25 constituting the N-channel MOS region 22, and they are grounded (GND) at their ends remote from the application lines. In these lines, therefore, the voltage division values (divided voltages) of the memory voltages based on the on-resistances of the memory cells M21-M25 and the corresponding pull-down resistors R221-R225 are applied to the corresponding gate electrodes G among the MOS transistors N21-N25, and the MOS transistors to which the divided voltages are applied are selectively activated. To the contrary, the lines which correspond to the cells under the off-states, among the memory cells M21-M25 are fixed to the ground (GND) potential by the corresponding pull-down resistors.

In this embodiment, in this manner, the memory cells M21-M25 constituting the nonvolatile memory region 21 function as switching elements for performing switching, in a manner to intervene in the application lines of the memory voltages. The on/off changeover of the application lines of the operating voltages (transistors L21-L25) is executed through the manipulations of the activation/inactivation of such application lines of the memory voltages (MOS transistors N21-N25).

Here, also in this embodiment, as the planar structure of the transistors L21-L25 constituting the LDMOS region 20 is shown in FIG. 4, the individual drain electrodes (regions) D are, in actuality, electrically connected with one another through a drain contact portion Dc which consists of a diffusion layer of N-type and a diffusion layer of high concentration (N⁺) that are formed within the semiconductor substrate C2. In addition, the end of the load to-be-operated Ld connected to the circuit power source Vc as is remote from this circuit power source is connected to the drain contact portion Dc through a suitable wiring. Likewise, the individual source electrodes (regions) S of the transistors L21-L25 are, in actuality, electrically connected with one another through a diffusion layer of high concentration (N⁺) which is disposed in a P well. In addition, the source electrodes (regions) S are held at the ground (GND) potential through a suitable wiring, together with a substrate contact portion Bc which is similarly formed as a diffusion layer of high concentration (P⁺) in the P well. In this way, the transistors L21-L25 constituting the LDMOS region 20 are respectively connected so as to intervene in the current path of the load to-be-operated Ld.

On the other hand, also here, as shown in FIG. 4, only the gate electrodes G of the transistors L21-L25 are formed in a manner to be electrically separated from one another in the LDMOS region 20, and the respective gate electrodes G are electrically connected through suitable wirings to the source electrodes S (FIG. 3) of the MOS transistors N21-N25 constituting the above N-channel MOS region 22. In addition, the operating voltages are selectively applied to the gate electrodes G as stated above, whereby channel layers (inversion layers) of channel length ChL are formed at parts directly under those gate electrodes of the gate electrodes G21-G25 to which the operating voltages are applied, and those transistors of the transistors L21-L25 which are formed with the channel layers are selectively activated. That is, currents flow through the formed channel layers. In other words, an effective channel width ChW at the time when the transistors L21-L25 are regarded as the single transistor becomes variable within the LDMOS region 20 in accordance with the number of the activated transistors.

Next, there will be described a method for adjusting the effective channel width ChW at the time when the LDMOS region 20 is regarded as the single transistor, in the semiconductor device configured as stated above. Incidentally, also the adjustment can be executed at will even after the manufacture of the semiconductor device, in the same manner as in the foregoing first embodiment.

In making the adjustment, the operating information which indicates whether or not the operating voltages are to be applied to the gate electrodes G (G21-G25) of the transistors L21-L25 (FIG. 3) is first set in the nonvolatile memory region 21. Also the setting of the operating information can be freely altered through a well-known memory manipulation. In this way, the predetermined voltages which correspond to the logic levels of the respective bits constituting the operating information are applied to the control gate electrodes CG of the memory cells M21-M25, thereby to selectively bring these memory cells into the on-states. Thus, currents flow from the memory power source Vm shown in FIG. 3, between the drain electrodes D and the source electrodes S of the memory cells (switching elements) brought into the on-states on the basis of the memory voltages applied to the drain electrodes D of the memory cells M21-M25, and through the pull-down resistors connected to the lines succeeding to these memory cells, and they lead to the ground (GND), respectively. In the lines through which the currents have flowed in this way, the divided voltages of the memory voltages based on the on-resistances of the memory cells under the on-states and the pull-down resistors corresponding thereto are applied to the gate electrodes G of the corresponding MOS transistors among the MOS transistors N21-N25, and the MOS transistors to which the divided voltages have been applied are activated.

When the MOS transistors N21-N25 are selectively activated on the basis of the operating information in this way, currents flow from the operating voltage input terminal Vin, between the drain electrodes D and source electrodes S of the activated MOS transistors, on the basis of the operating voltages applied to the drain electrodes D of the MOS transistors N21-N25. In addition, the currents flow through the pull-down resistors connected to the lines which succeed to the MOS transistors, and they lead to the ground (GND). In the lines through which the currents have flowed in this way, the divided voltages of the operating voltages based on the on-resistances of the activated MOS transistors and the pull-down resistors corresponding thereto are applied to the gate electrodes G of the corresponding transistors among the transistors L21-L25, and the transistors to which the divided voltages have been applied are activated. That is, current fed from the circuit power source Vc to the load to-be-operated Ld flows through only the activated transistors, and the effective channel width ChW at the time when the activated transistors L21-L25 are regarded as the single transistor is made variable within the semiconductor substrate C2.

As described above, in accordance with the semiconductor device according to the second embodiment, advantages to be listed below are obtained.

(1) The operating information which indicates whether or not the operating voltages are to be applied to the gate electrodes G (G21-G25) of the transistors L21-L25 constituting the LDMOS region 20 is variably set in the memory cells M21-M25. In addition, the transistors L21-L25 are selectively activated on the basis of the operating information, through the operations of the MOS transistors N21-N25 which are connected in a manner to respectively intervene in the application lines of the operating voltages to the gate electrodes G of the transistors L21-L25. Thus, even after the manufacture of the semiconductor device, the required values of the on-resistance, the switching time, etc. at the time when the transistors L21-L25 are regarded as the single transistor can be adjusted through the application aspect of the operating voltages to the gate electrodes G (G21-G25). Accordingly, even in the case, for example, where the readjustments of the required values are needed due to the alteration of the load, or the like, the adjustments and alterations of the required values can be coped with at a high degree of freedom. Moreover, in this case, owing to the intervention of the MOS transistors N21-N25, the gate resistors of the transistors L21-L25 and the on-resistances of the memory cells M21-M25 constructing the switching elements can be independently set unlike in the foregoing first embodiment.

(2) The LDMOS region 20 and the nonvolatile memory region 21 are formed on the identical semiconductor substrate C2. Thus, reduction in size can be attained as the semiconductor device. Besides, as regards the transistors L21-L25 constituting the LDMOS region 20, the memory cells M21-M25 constituting the nonvolatile memory region 21, and the MOS transistors N21-N25 constituting the N-channel MOS region 22, many of semiconductor manufacturing processes are common, and hence, reduction in the manufacturing man-hour of the semiconductor device can also be attained.

(3) The drain electrodes (regions) D and source electrodes (regions) S of the transistors L21-L25 are electrically connected through the diffusion layers, respectively. Thus, it is dispensed with to lay metallic wirings or the like which serve to electrically connect the transistors L21-L25 in parallel with the path of the current extending from the circuit power source Vc to the ground (GND), so that the simplification of the structure, as well as the simplification of the manufacturing process can be attained. Moreover, as compared with the case of laying the metallic wirings or the likes, the embodiment sweeps off the apprehension of disconnection, etc., so that the semiconductor device of higher reliability can be realized.

Incidentally, the first and second embodiments described above can also be performed by appropriately altering them in, for example, aspects stated below.

The first and second embodiments have adopted the structure in which the drain electrodes D and source electrodes S of the transistors L11-L15 or the transistors L21-L25 are electrically connected through the diffusion layers formed in the semiconductor substrate C1 or C2, respectively. However, this structure is not restrictive, but it is also allowed to adopt a structure in which, not only the gate electrodes G, but also the drain electrodes D and the source electrodes S are respectively isolated on the semiconductor substrate, whereupon they are electrically connected through suitable wirings.

In the first and second embodiments, the nonvolatile memory region 11 or 21 or the N-channel MOS region 22 has been collectively formed in the single semiconductor substrate C1 or C2 formed with the LDMOS region 10 or 20, but this configuration is not restrictive. Alternatively, it is also allowed, for example, that the memory cells M11-M15 or M21-M25 constituting the nonvolatile memory region 11 or 21, and the MOS transistors N21-N25 constituting the N-channel MOS region 22 are formed in another semiconductor substrate, and that they are respectively connected to the transistors L11-L15 or L21-L25 constituting the LDMOS region 10 or 20 formed in the semiconductor substrate C1 or C2, through suitable wirings. In short, an aspect for realization is as desired with any structure in which the equivalent circuit shown in FIG. 1 or FIG. 3 before is realized, that is, with any configuration in which the operating information that indicates whether or not the operating voltages are to be applied to the gate electrodes of the transistors is variably set in the nonvolatile memory region, and in which the transistors that have the operating voltages applied to their gate electrodes are selectively activated on the basis of the operating information.

### Third Embodiment

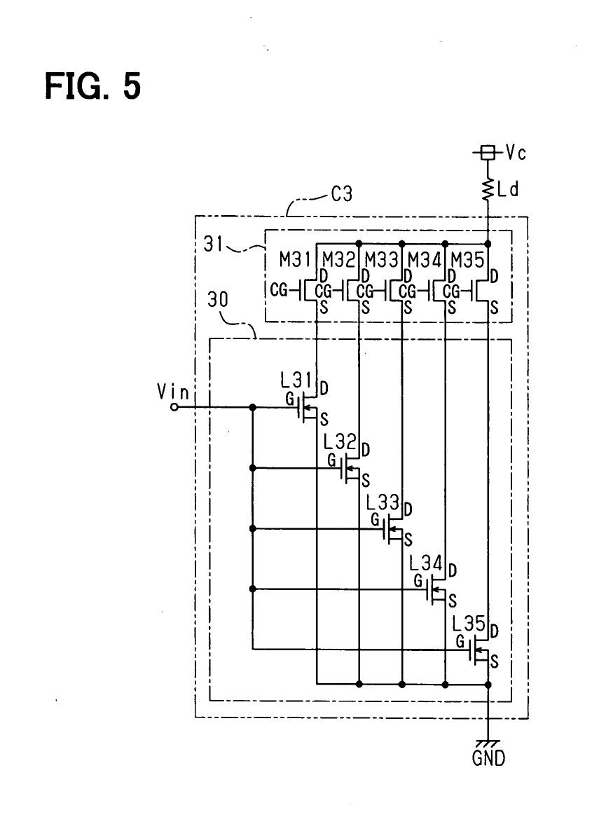

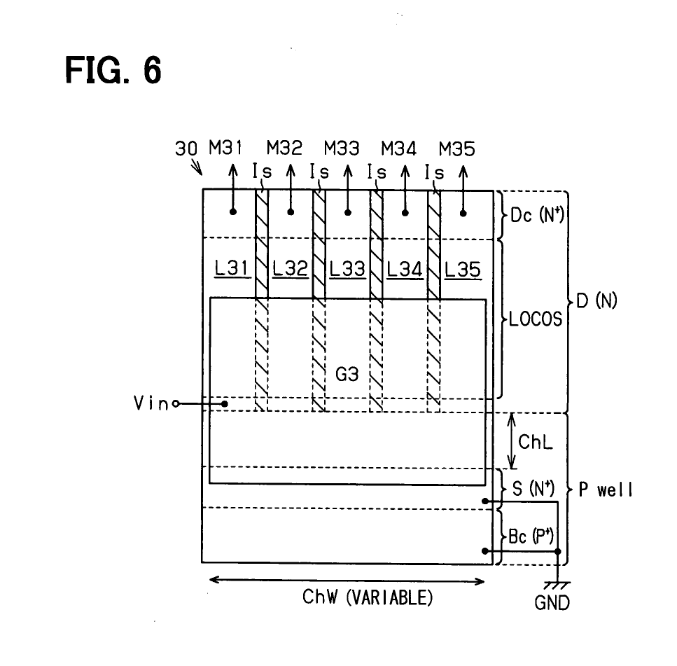

Next, a third embodiment of a semiconductor device according to this invention will be described with reference to FIGS. 5 and 6.

Also the semiconductor device of this embodiment has a configuration which basically conforms to the first embodiment shown in FIGS. 1 and 2 before, namely, a configuration in which a transistor having an LDMOS structure is arrayed and formed in a semiconductor substrate in a manner to be divided into a plurality of transistors that are electrically connected in parallel with the path of current. In this embodiment, however, operating information which indicates whether or not currents are to be fed to the plurality of transistors constituting the LDMOS region can be variably set in a plurality of memory cells constituting a nonvolatile memory region within the identical semiconductor substrate. In addition, the currents flow selectively through those transistors of the plurality of transistors to which the currents are to be fed, on the basis of the set operating information.

FIG. 5 shows a general equivalent circuit centering around the semiconductor substrate on which such a semiconductor device is packaged, and including a load to-be-operated, while FIG. 6 schematically shows a planar structure in relation to the LDMOS region which is formed in the semiconductor substrate.

First, as shown in FIG. 5, the semiconductor substrate C3 on which the semiconductor device of this embodiment is packaged is disposed in a manner to intervene in that path of current which extends from a circuit power source Vc to the ground (GND) through the load to-be-operated Ld, in the same manner as in the foregoing first embodiment. The semiconductor substrate C3 is basically configured including the LDMOS region 30 which is a transistor region having the LDMOS structure, and the nonvolatile memory region 31 which is a region where the operating information is variably set.

In the LDMOS region 30 of them, in the same manner as in the foregoing first embodiment, the transistor having the LDMOS structure is arrayed and formed in the semiconductor substrate C3 in a manner to be divided into, for example, five transistors L31-L35 which are electrically connected in parallel with the path of the current. Each of the transistors L31-L35 has a structure conforming to the LDMOS structure exemplified in FIG. 26 before, and it is configured including a drain electrode D and a source electrode S, and a gate electrode G which controls current flowing between the drain electrode D and the source electrode S. In the transistors L31-L35, however, the respective drain electrodes D are connected to corresponding memory cells M31-M35 which constitute the nonvolatile memory region 31, and the gate electrodes G are connected directly to, and electrically in parallel with, an operating voltage input terminal Vin to which operating voltages are inputted.

Besides, the five memory cells M31-M35 in the same number as that of the transistors L31-L35 are formed in the nonvolatile memory region 31 which is formed of an electrically rewritable nonvolatile memory (for example, EPROM), also in the same manner as in the foregoing first embodiment. Also each of the memory cells M31-M35 has a MOS structure basically, and as shown in FIG. 5, it includes a drain electrode D and a source electrode S which are connected to the path of the current, and a control gate electrode CG which controls whether or not current is to flow between the drain electrode D and the source electrode S, on the basis of the voltage applied in accordance with the operating information. In addition, the respective drain electrodes D of the memory cells M31-M35 are electrically connected in parallel with that end of the load to-be-operated Ld connected to the circuit power source Vc which is remote from this circuit power source, through a suitable wiring, and the respective source electrodes S of the memory cells M31-M35 are connected to the drain electrodes D of the corresponding transistors L31-L35.

Incidentally, the control gate electrodes CG of the memory cells M31-M35 are connected to a voltage control circuit (not shown) in the same manner as in the foregoing first embodiment. In addition, predetermined voltages which correspond to the logic levels of rewritable information items of 5 bits constituting the operating information of the transistors L31-L35 are applied to the respective control gate electrodes CG through the voltage control circuit. Concretely, a voltage at a magnitude which brings the corresponding memory cell into an on-state is applied to the control gate electrode CG of the memory cell which corresponds to the bit that lies at, for example, a logic H (high) level among the bits constituting the operating information. Thus, the current feed to the transistor connected to a stage succeeding to the corresponding memory cell is permitted. On the other hand, a voltage at a magnitude which brings the corresponding memory cell into an off-state is applied to the control gate electrode CG of the memory cell which corresponds to the bit that lies at, for example, a logic L (low) level among the bits constituting the operating information. Thus, the current feed to the transistor connected to a stage succeeding to the corresponding memory cell is inhibited. In this way, the memory cells M31-M35 constituting the nonvolatile memory region 31 function as switching elements for performing the switching (on/off) of the transistors L31-L35, in a manner to intervene in lines which couple the source electrodes S of the memory cells M31-M35 and the drain electrodes D of the transistors L31-L35 constituting the LDMOS region 30, that is, current feed paths.

Here, in this embodiment, as the planar structure of the transistors L31-L35 is shown in FIG. 6, the individual gate electrodes G thereof are, in actuality, formed as a single gate electrode G3 which corresponds to all the channel regions of the transistors L31-L35 in the LDMOS region 30. On the other hand, the individual drain electrodes (regions) D of the transistors L31-L35 are, in actuality, formed in such a manner that drain contact portions Dc which consist of a diffusion layer of N-type and a diffusion layer of high concentration (N⁺) that are formed within the semiconductor substrate C3 are respectively separated by isolation layers Is. In addition, the source electrodes S of the memory cells M31-M35 are electrically connected to the respective drain contact portions Dc thus separated, through suitable wirings. On the other hand, the individual source electrodes (regions) S of the transistors L31-L35 are, in actuality, electrically connected with one another through a diffusion layer of high concentration (N⁺) which is disposed in a P well. Incidentally, the source electrodes (regions) S are held at the ground (GND) potential through a suitable wiring, together with a substrate contact portion Bc which is similarly formed as a diffusion layer of high concentration (P⁺) in the P well. In this way, the transistors L31-L35 constituting the LDMOS region 30 are respectively connected so as to intervene in the current path of the load to-be-operated Ld.

In addition, the operating voltages are applied in common from the operating voltage input terminal Vin to the individual gate electrodes G of the transistors L31-L35, that is, the single gate electrode G3, whereby a channel layer (inversion layer) of channel length ChL is formed at a part directly under the gate electrode G3. However, in spite of such formation of the channel layer for all the transistors L31-L35, in the case where the memory cells M31-M35 are selectively brought into the on-states, actually currents fed from the circuit power source Vc flow through only the transistors which correspond to the selected memory cells. In this way, among the transistors L31-L35, only the transistors in which the currents have actually flowed through their channel layers are selectively activated. That is, also in this case, an effective channel width ChW at the time when the transistors L31-L35 are regarded as a single transistor becomes variable within the LDMOS region 30 in accordance with the number of the activated transistors.

Next, there will be described a method for adjusting the effective channel width ChW at the time when the LDMOS region 30 is regarded as the single transistor, in the semiconductor device configured as stated above. Incidentally, also the adjustment can be executed at will even after the manufacture of the semiconductor device, in the same manner as in the foregoing first and other embodiments.

In making the adjustment, the operating voltages are first applied in common from the operating voltage input terminal Vin to the gate electrodes G (single gate electrode G3) of the transistors L31-L35 (FIG. 5), thereby to form the channel layer (inversion layer) at the part directly under the gate electrode G3. On the other hand, the operating information which indicates whether or not the currents are to be fed to the transistors L31-L35 (FIG. 5) is set in the nonvolatile memory region 31. It is as stated before that the setting of the operating information can be freely altered through a well-known memory manipulation. In this way, the predetermined voltages which correspond to the logic levels of the respective bits constituting the operating information are applied to the control gate electrodes CG of the memory cells M31-M35, thereby to selectively bring these memory cells into the on-states. Thus, the current fed from the circuit power source Vc to the load to-be-operated Ld as shown in FIG. 5 flows between the drain electrodes D and the source electrodes S of only the memory cells (switching elements) brought into the on-states, and through the transistors connected to the lines succeeding to these memory cells, and they lead to the ground (GND) while activating these transistors, respectively. In addition, the effective channel width ChW at the time when the transistors L31-L35 are regarded as the single transistor becomes variable within the semiconductor substrate C3 in accordance with the number of the activated transistors.

As described above, in accordance with the semiconductor device according to the third embodiment, advantages to be listed below are obtained.

(1) The operating information which indicates whether or not the currents are to be fed to the transistors L31-L35 constituting the LDMOS region 30 is variably set in the memory cells M31-M35 constituting the nonvolatile memory region 31, and those transistors of the transistors L31-L35 to which the currents are to be fed are selectively fed with the currents on the basis of the operating information. Thus, even after the manufacture of the semiconductor device, the required values of the on-resistance, the switching time, etc. at the time when the transistors L31-L35 are regarded as the single transistor can be adjusted through the aspect of the current feed to the transistors L31-L35. Accordingly, even in the case, for example, where the readjustments of the required values are needed due to the alteration of the load, or the like, the adjustments and alterations of the required values can be coped with at a high degree of freedom.

(2) The LDMOS region 30 and the nonvolatile memory region 31 are formed on the identical semiconductor substrate C3. Thus, reduction in size can be attained as the semiconductor device. Besides, as regards the transistors L31-L35 constituting the LDMOS region 30, and the memory cells M31-M35 constituting the nonvolatile memory region 31, many of semiconductor manufacturing processes are common, and hence, reduction in the manufacturing man-hour of the semiconductor device can be attained.

(3) The gate electrodes G of the transistors L31-L35 are formed as the single gate electrode G3 which corresponds to all the channel regions of the transistors L31-L35. Thus, it is dispensed with to lay metallic wirings or the like which serve to apply the operating voltages in common to the gate electrodes G of the transistors L31-L35, so that the simplification of the structure, as well as the simplification of the manufacture can be attained. Moreover, as compared with the case of laying the metallic wirings or the like, the embodiment sweeps off the apprehension of disconnection, etc., so that the semiconductor device of higher reliability can be realized. Incidentally, this holds true also of the source electrodes S which are electrically connected through the diffusion layer in the transistors L31-L35.

### Fourth Embodiment

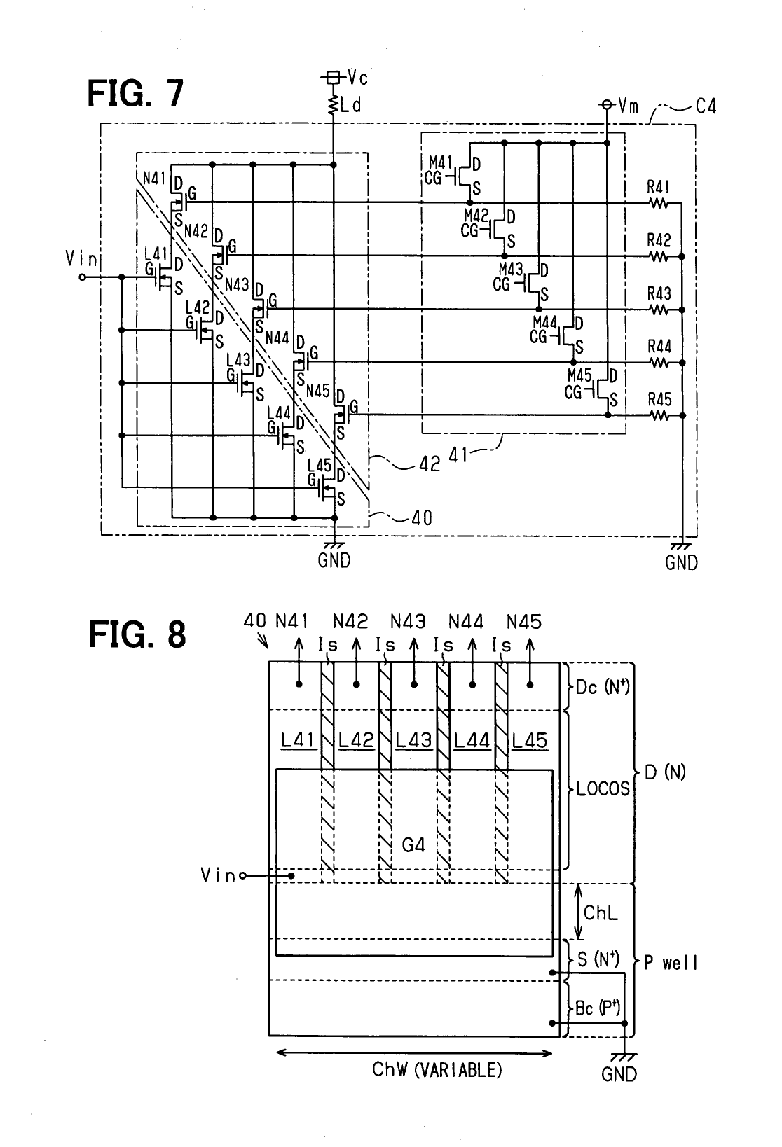

Next, a fourth embodiment of a semiconductor device according to this invention will be described with reference to FIGS. 7 and 8.

Also the semiconductor device of this embodiment has a configuration which basically conforms to the first embodiment shown in FIGS. 1 and 2 before, namely, a configuration in which a transistor having an LDMOS structure is arrayed and formed in a semiconductor substrate in a manner to be divided into a plurality of transistors that are electrically connected in parallel with the path of current. In addition, also in this embodiment, basically in the same manner as in the third embodiment, operating information which indicates whether or not currents are to be fed to the plurality of transistors constituting the LDMOS region can be variably set in a plurality of memory cells constituting a nonvolatile memory region within the identical semiconductor substrate. Here, however, the currents are selectively fed to those transistors of the plurality of transistors to which the currents are to be fed, on the basis of the set operating information, through the operations of a plurality of MOS transistors which are connected in a manner to intervene in current feed paths to the plurality of transistors.

FIG. 7 shows a general equivalent circuit centering around the semiconductor substrate on which such a semiconductor device is packaged, and including a load to-be-operated, while FIG. 8 schematically shows a planar structure in relation to the LDMOS region which is formed in the semiconductor substrate.

First, as shown in FIG. 7, the semiconductor substrate C4 on which the semiconductor device of this embodiment is packaged is disposed in a manner to intervene in that path of current which extends from a circuit power source Vc to the ground (GND) through the load to-be-operated Ld, in the same manner as in the foregoing first embodiment. The semiconductor substrate C4 is basically configured including the LDMOS region 40 which is a transistor region having the LDMOS structure, the nonvolatile memory region 41 which is a region where the operating information is variably set, and an N-channel MOS region 42 which is connected in a manner to intervene in the current feed paths to the LDMOS region 40.

In the LDMOS region 40 of them, in the same manner as in the foregoing first embodiment, the transistor having the LDMOS structure is arrayed and formed in the semiconductor substrate C4 in a manner to be divided into, for example, five transistors L41-L45 which are electrically connected in parallel with the path of the current. Each of the transistors L41-L45 has a structure conforming to the LDMOS structure exemplified in FIG. 26 before, and it is configured including a drain electrode D and a source electrode S, and a gate electrode G which controls current flowing between the drain electrode D and the source electrode S. In addition, in the transistors L41-L45, the respective drain electrodes D are connected to the corresponding MOS transistors which constitute the N-channel MOS region 42, and the gate electrodes G are connected directly to, and electrically in parallel with, an operating voltage input terminal Vin to which operating voltages are inputted.

Besides, the five memory cells M41-M45 in the same number as that of the transistors L41-L45 are formed in the nonvolatile memory region 41. Also each of the memory cells M41-M45 has a MOS structure basically, and as shown in FIG. 7, it includes a drain electrode D and a source electrode S, and a control gate electrode CG which controls whether or not current is to flow between the drain electrode D and the source electrode S, on the basis of a voltage applied in accordance with the operating information. In addition, the respective drain electrodes D of the memory cells M41-M45 are electrically connected in parallel with a memory power source Vm, and the respective source electrodes S of the memory cells M41-M45 are connected to the gate electrodes G of the corresponding MOS transistors N41-N45 constituting the N-channel MOS region.

Incidentally, the control gate electrodes CG of the memory cells M41-M45 are connected to a voltage control circuit (not shown) in the same manner as in the foregoing first embodiment. In addition, predetermined voltages which correspond to the logic levels of rewritable information items of 5 bits constituting the operating information of the transistors L41-L45 are applied to the respective control gate electrodes CG through the voltage control circuit. Concretely, a voltage at a magnitude which brings the corresponding memory cell into an on-state is applied to the control gate electrode CG of the memory cell which corresponds to the bit that lies at, for example, a logic H (high) level among the bits constituting the operating information. On the other hand, a voltage at a magnitude which brings the corresponding memory cell into an off-state is applied to the control gate electrode CG of the memory cell which corresponds to the bit that lies at, for example, a logic L (low) level among the bits constituting the operating information.

Besides, the five MOS transistors N41-N45 in the same number as that of the transistors L41-L45 are formed in the N-channel MOS region 42. The respective drain electrodes D of the MOS transistors N41-N45 are electrically connected in parallel with that end of the load to-be-operated Ld connected to the circuit power source Vc which is remote from this circuit power source, through a suitable wiring, and the respective source electrodes S of the MOS transistors N41-N45 are connected to the drain electrodes D of the corresponding transistors L41-L45.

Meanwhile, as shown in FIG. 7, pull-down resistors R41-R45 are connected to the application lines of the memory voltages to the respective gate electrodes G of the MOS transistors N41-N45 constituting the N-channel MOS region 42, that is, common nodes with the respective source electrodes S of the memory cells M41-M45 constituting the nonvolatile memory region 41, and these pull-down resistors are grounded at their ends remote from the common nodes. In these lines, therefore, the voltage division values (divided voltages) of the memory voltages based on the on-resistances of the memory cells M41-M45 and the corresponding pull-down resistors R41-R45 are applied to the corresponding gate electrodes G among the MOS transistors N41-N45, and the MOS transistors to which the divided voltages are applied are selectively activated. To the contrary, the lines which correspond to the cells under the off-states, among the memory cells M41-M45 are fixed to the ground (GND) potential by the corresponding pull-down resistors.

In this manner, the memory cells M41-M45 constituting the nonvolatile memory region 41 function as switching elements for performing switching, in a manner to intervene in the application lines of the memory voltages. That is, the switching elements execute the on/off of the application lines of the memory voltages, in turn, the changeover of the activation/inactivation of the MOS transistors N41-N45. In addition, the on/off changeover of the current feed paths to the transistors L41-L45 connected at the succeeding stages is executed through the activation/inactivation manipulations of the MOS transistors N41-N45.

Here, in this embodiment, as the planar structure of the transistors L41-L45 is shown in FIG. 8, the individual gate electrodes G thereof are, in actuality, formed as a single gate electrode G4 which corresponds to all the channel regions of the transistors L41-L45 in the LDMOS region 40. On the other hand, the individual drain electrodes (regions) D of the transistors L41-L45 are, in actuality, formed in such a manner that drain contact portions Dc which consist of a diffusion layer of N-type and a diffusion layer of high concentration (N⁺) that are formed within the semiconductor substrate C4 are respectively separated by isolation layers Is. In addition, the source electrodes S of the MOS transistors N41-N45 are electrically connected in series with the respective drain contact portions Dc thus isolated, through suitable wirings. On the other hand, the individual source electrodes (regions) S of the transistors L41-L45 are, in actuality, electrically connected with one another through a diffusion layer of high concentration (N⁺) which is disposed in a P well. Incidentally, the source electrodes (regions) S are held at the ground (GND) potential through a suitable wiring, together with a substrate contact portion Bc which is similarly formed as a diffusion layer of high concentration (P⁺) in the P well. In this way, the transistors L41-L45 constituting the LDMOS region 40 are respectively connected so as to intervene in the current path of the load to-be-operated Ld.

In addition, the operating voltages are applied in common from the operating voltage input terminal Vin to the individual gate electrodes G of the transistors L41-L45, that is, the single gate electrode G4, whereby a channel layer (inversion layer) of channel length ChL is formed at a part directly under the gate electrode G4. However, in spite of such formation of the channel layer for all the transistors L41-L45, in the case where the MOS transistors N41-N45 are selectively brought into the on-states, actually currents fed from the circuit power source Vc flow through only the transistors (L41-L45) which correspond to the selected MOS transistors. In this way, among the transistors L41-L45, only the transistors in which the currents have actually flowed through their channel layers are selectively activated. That is, also in this case, an effective channel width ChW at the time when the transistors L41-L45 are regarded as a single transistor becomes variable within the LDMOS region 40 in accordance with the number of the activated transistors.

Next, there will be described a method for adjusting the effective channel width ChW at the time when the LDMOS region 40 is regarded as the single transistor, in the semiconductor device configured as stated above. Incidentally, also the adjustment can be executed at will even after the manufacture of the semiconductor device, in the same manner as in the foregoing first and other embodiments.

In making the adjustment, the operating voltages are first applied in common from the operating voltage input terminal Vin to the gate electrodes G (single gate electrode G4) of the transistors L41-L45 (FIG. 7), thereby to form the channel layer (inversion layer) at the part directly under the gate electrode G4. On the other hand, the operating information which indicates whether or not the currents are to be fed to the transistors L41-L45 (FIG. 7) is set in the nonvolatile memory region 41. Also the setting of the operating information can be freely altered through a well-known memory manipulation. In this way, the predetermined voltages which correspond to the logic levels of the respective bits constituting the operating information are applied to the control gate electrodes CG of the memory cells M41-M45, thereby to selectively bring these memory cells into the on-states. Thus, currents flow from the memory power source Vm shown in FIG. 7, between the drain electrodes D and the source electrodes S of the memory cells (switching elements) brought into the on-states on the basis of the memory voltages applied to the drain electrodes D of the memory cells M41-M45, and through the pull-down resistors connected to the lines succeeding to these memory cells, and they lead to the ground (GND), respectively. In the lines through which the currents have flowed in this way, the divided voltages of the memory voltages based on the on-resistances of the memory cells under the on-states and the pull-down resistors corresponding thereto are applied to the gate electrodes G of the corresponding MOS transistors among the MOS transistors N41-N45, and the MOS transistors to which the divided voltages have been applied are activated. In addition, the current fed from the circuit power source Vc to the load to-be-operated Ld as shown in FIG. 7 flows between the drain electrodes D and the source electrodes S of only the MOS transistors brought into the on-states, and through the transistors connected to the lines succeeding to these MOS transistors, and they lead to the ground (GND) while activating these transistors, respectively. In addition, the effective channel width ChW at the time when the transistors L41-L45 are regarded as the single transistor becomes variable within the semiconductor substrate C4 in accordance with the number of the activated transistors.

As described above, in accordance with the semiconductor device according to the fourth embodiment, advantages to be listed below are obtained.

(1) The operating information which indicates whether or not the currents are to be fed to the transistors L41-L45 constituting the LDMOS region 40 is variably set in the memory cells M41-M45 constituting the nonvolatile memory region 41. In addition, those transistors of the transistors L41-L45 to which the currents are to be fed are selectively fed with the currents on the basis of the operating information, through the operations of the MOS transistors N41-N45 which are connected in a manner to intervene in the current feed paths to these transistors L41-L45. Thus, even after the manufacture of the semiconductor device, the required values of the on-resistance, the switching time, etc. at the time when the transistors L41-L45 are regarded as the single transistor can be adjusted through the aspect of the current feed to the transistors L41-L45. Accordingly, even in the case, for example, where the readjustments of the required values are needed due to the alteration of the load, or the like, the adjustments and alterations of the required values can be coped with at a high degree of freedom. Moreover, in this case, owing to the intervention of the MOS transistors N41-N45, the gate resistors of the transistors L41-L45 and the on-resistances of the memory cells M41-M45 constructing the switching elements can be independently set unlike in the foregoing third embodiment.

(2) The LDMOS region 40 and the nonvolatile memory region 41 are formed on the identical semiconductor substrate C4. Thus, reduction in size can be attained as the semiconductor device. Besides, as regards the transistors L41-L45 constituting the LDMOS region 40, the memory cells M41-M45 constituting the nonvolatile memory region 41, and the MOS transistors N41-N45 constituting the N-channel MOS region 42, many of semiconductor manufacturing processes are common, and hence, reduction in the manufacturing man-hour of the semiconductor device can be attained.

### Fifth Embodiment

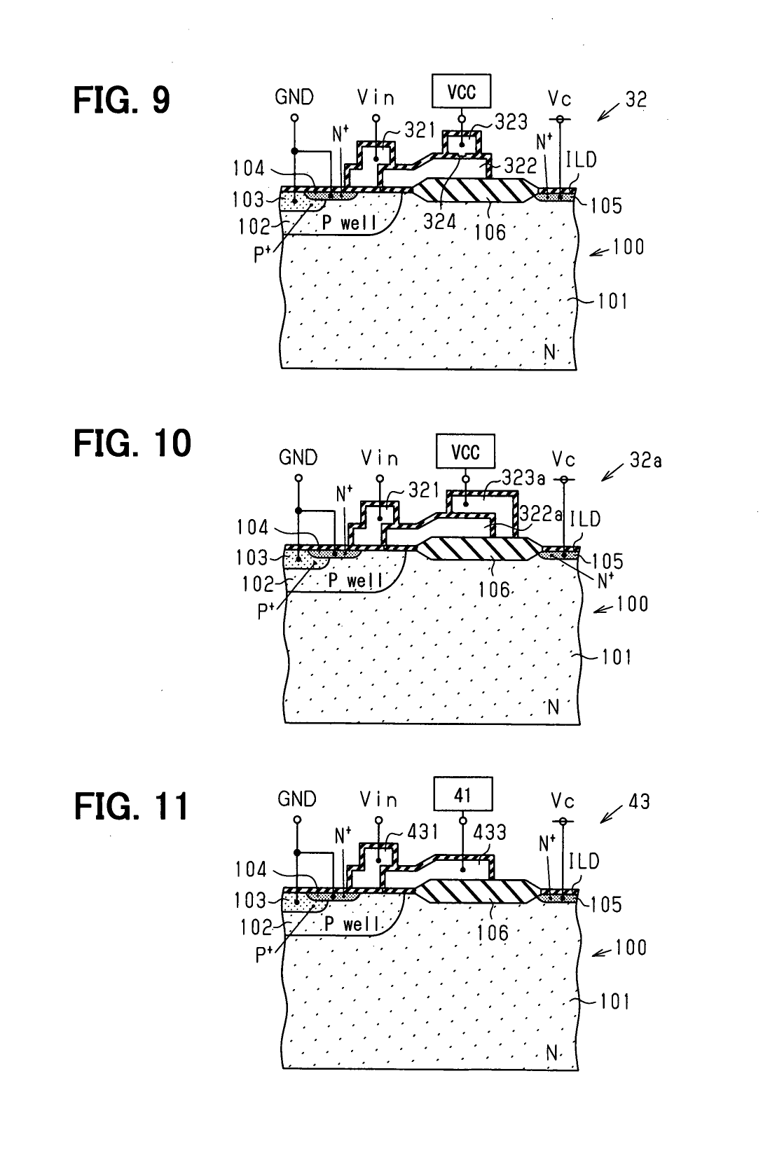

Next, a fifth embodiment of a semiconductor device according to this invention will be described with reference to FIG. 9.

The semiconductor device of this embodiment has a configuration which basically conforms to the third embodiment shown in FIGS. 5 and 6 before. In this embodiment, however, memory cells M31-M35 constituting a nonvolatile memory region 31 are respectively built in transistors L31-L35 constituting an LDMOS region 30.

FIG. 9 schematically shows an example of the side sectional structure of such an LDMOS transistor in which a nonvolatile memory is built.

In this embodiment, an electrically rewritable EPROM is adopted as the nonvolatile memory, and as shown in FIG. 9, the transistor 32 having the built-in memory is basically configured including on the semiconductor substrate 100, a gate electrode 321 which is connected to an operating voltage input terminal Vin by a suitable wiring, a floating gate electrode 322 which is formed in adjacency to the gate electrode 321, a tunnel film 324 which is formed on the floating gate electrode 322, and a control gate electrode 323 which is stacked and formed on the tunnel film 324 and which is connected to a voltage control circuit (not shown) by a suitable wiring, and so on.

Here, the transistor 32 having the built-in memory corresponds to the memory cell and the transistor in one set as are connected with each other by a suitable wiring, among the memory cells M31-M35 and the transistors L31-L35 shown in FIG. 5 before. Besides, the gate electrode 321 corresponds to the gate electrodes G of the transistors L31-L35, and the control gate electrode 323 to the gate electrodes G of the memory cells M31-M35.

Operating information which indicates whether or not current is to be fed to the transistor is set for such a transistor 32 having the built-in memory, through the operation of the voltage control circuit. More specifically, a voltage at a predetermined magnitude higher than the ground (GND) as corresponds to a bit which lies at a logic H (high) level (at which the current is to be fed), among individual bits constituting the operating information, is applied to the control gate electrode 323 of the transistor 32 having the built-in memory, by the voltage control circuit. Thus, electrons existing within the floating gate electrode 322 are extracted onto the side of the control gate electrode 323 through the tunnel film 324, and the transistor 32 having the built-in memory is brought into an on-state. On the other hand, a voltage at a predetermined magnitude lower than the ground (GND) as corresponds to a bit which lies at a logic (L) low level (at which the current is not to be fed), among the individual bits constituting the operating information, is applied to the control gate electrode 323 of the transistor 32 having the built-in memory, by the voltage control circuit. Thus, electrons are injected from the control gate electrode 323 onto the side of the floating gate electrode 322 through the tunnel film 324, and the transistor 32 having the built-in memory is brought into an off-state. In this manner, the transistor 32 having the built-in memory functions as a switching element whose on/off-states are respectively changed-over in accordance with the logic levels of the bits constituting the operating information.

Next, there will be described a method for adjusting an effective channel width at the time when the LDMOS region is regarded as a single transistor, in the semiconductor device configured as stated above. Incidentally, it is as stated before that the adjustment can be executed at will even after the manufacture of the semiconductor device.

In making the adjustment, predetermined operating voltages are first applied from the operating voltage input terminal Vin to the gate electrodes 321 of the transistors, whereby channel layers (inversion layers) are formed at the parts of channel regions 102 directly under the gate electrodes 321. The channel layers thus formed lie in touch with source regions 104 and are therefore electrically connected, whereas they do not lie in touch with a drain region 101 and are not electrically connected.

Meanwhile, the voltage control circuit is operated, whereby the on/off of the respective bits of the operating information are set on the basis of the exchanges of the electrons through the tunnel films 324 between the control gate electrodes 323 and the floating gate electrodes 322 as correspond to potentials applied to the control gate electrodes 323. On this occasion, when the transistors 32 having the built-in memories are brought into the on-states, channel layers (inversion layers) are formed at the parts of the channel regions 102 directly under the floating gate electrodes 322. The channel layers thus formed lie in touch with the drain region 101 and the foregoing channel layers formed at the parts directly under the gate electrodes 321, and they are therefore electrically connected.

In this way, when predetermined voltages are respectively applied selectively to the control gate electrodes 323 of the transistors 32 having the built-in memories and in common to the gate electrodes 321 of the transistors, current fed from a circuit power source Vc flows only between the drain region 101 and source regions 104 of the transistors 32 having the built-in memories, under the on-states, and it leads to the ground (GND). In this way, the effective channel width at the time when the transistors are regarded as the single transistor is made variable within the semiconductor substrate in accordance with the number of the transistors which are selectively activated on the basis of the operating information of the transistors set in the nonvolatile memory region.

Advantages equivalent to those of the third embodiment are attained also by the semiconductor device according to the fifth embodiment described above.

Incidentally, the fifth embodiment can also be performed through an appropriate alteration in, for example, an aspect stated below.

In the fifth embodiment, the channel layer has been formed at the part of the channel region 102 directly under the floating gate electrode 322, on the basis of the exchanges of the electrons through the tunnel film 324 between the control gate electrode 323 and the floating gate electrode 322, but a channel for forming the channel layer is not restricted to this aspect. As shown in FIG. 10 as a figure corresponding to FIG. 9, the control gate electrode 323a of a transistor 32a having a built-in memory is stacked and formed on a floating gate electrode 322a so as to cover the corner part of the floating gate electrode 322a. In addition, the on/off of each bit of operating information is set by utilizing an electric field concentration at the corner part of the floating gate electrode 322a as corresponds to a potential applied to the control gate electrode 323a through the operation of a voltage control circuit. Also in this way, advantages equivalent to those of the foregoing fifth embodiment, that is, the third embodiment are attained.

### Sixth Embodiment

Next, a sixth embodiment of a semiconductor device according to this invention will be described with reference to FIG. 11.

The semiconductor device of this embodiment has a configuration which basically conforms to the fourth embodiment shown in FIGS. 7 and 8 before. In this embodiment, however, MOS transistors N41-N45 constituting an N-channel MOS 42 are respectively built in transistors L41-L45 constituting an LDMOS region 40.

FIG. 11 schematically shows an example of the side sectional structure of such a transistor.

As shown in FIG. 11, the transistor 43 having such a built-in MOS transistor is basically configured including on the semiconductor substrate 100, a gate electrode 431 which is connected to an operating voltage input terminal Vin by a suitable wiring, a gate electrode 433 which is formed in adjacency to the gate electrode 431 and which is connected to a memory region 41 (not shown) by a suitable wiring, and so on.

Here, the transistor 43 corresponds to the MOS transistor and the transistor in one set as are connected with each other by a suitable wiring, among the MOS transistors N41-N45 and the transistors L41-L45 shown in FIG. 7 before. Besides, the gate electrode 431 corresponds to the gate electrodes G of the transistors L41-L45, and the gate electrode 433 to the gate electrodes G of the MOS transistors N41-N45. In this way, the transistor 43 is formed as a transistor which shares the channel region of the transistors L41-L45 and the channel region of the MOS transistors N41-N45.

Next, there will be described a method for adjusting an effective channel width at the time when the LDMOS region is regarded as a single transistor, in the semiconductor device configured in this manner. Incidentally, the adjustment can be executed at will even after the manufacture of the semiconductor device.

In making the adjustment, predetermined operating voltages are first applied from the operating voltage input terminal Vin to the gate electrodes 431 of the transistors 43, whereby channel layers (inversion layers) are formed at the parts of channel regions 102 directly under the gate electrodes 431. Incidentally, the channel layers thus formed lie in touch with source regions 104 and are electrically connected, whereas they do not lie in touch with a drain region 101 and are not electrically connected. However, in the case where the memory cells M41-M45 constituting the nonvolatile memory region 41 (FIG. 7) are turned on, channel layers (inversion layers) are formed at the parts of the channel regions 102 directly under the gate electrodes 433, and hence, they are connected with the above channel layers formed directly under the gate electrodes 431. That is, the drain region 101 and the source regions 104 are electrically connected through the formed channel layers.

In this way, when predetermined voltages are respectively applied selectively to the memory cells constituting the nonvolatile memory region 41 and in common to the gate electrodes 431 of the transistors, current fed from a circuit power source Vc flows only between the drain region 101 and source regions 104 of the transistors 43 under the on-states, and it leads to the ground (GND). In this way, the effective channel width at the time when the transistors are regarded as the single transistor is made variable within the semiconductor substrate in accordance with the number of the transistors which are selectively activated on the basis of the operating information of the transistors variably set in the nonvolatile memory region.

Advantages equivalent to those of the fourth embodiment are attained also by the semiconductor device according to the sixth embodiment described above.

Moreover, in the semiconductor device according to the sixth embodiment, after the formation of each second gate electrodes 433, the corresponding first gate electrodes 431 has been formed so as to partly overlap the second gate electrodes 433, so that increases in the threshold voltage and on-resistance of the transistor 43 can be suppressed.

More specifically, in this embodiment, voltages different from each other need to be fed to the first gate electrode 431 and the second gate electrode 433 which are formed in adjacency. Therefore, both the gate electrodes 431 and 433 need to be held in an open state electrically therebetween. As a method for separating the gate electrodes 431 and 433, there is considered, for example, a method in which the gate electrode 107 shown in FIG. 26 is divided into the first gate electrode and the second gate electrode by etching or the like expedient. With this method, however, when the first gate electrode and the second gate electrode are excessively spaced, the channel layers formed in the P well 102 by both the gate electrodes are not connected, and the transistor becomes difficult to turn on. Therefore, in the case where the first gate electrode and the second gate electrode are formed by such a method and where they are excessively spaced, high voltages must be applied in accordance with the substantial interval between both the gate electrodes. This is equivalent to operating a transistor which is formed with thick gate insulating films, and the increases in the threshold voltage and on-resistance of the transistor are incurred.

In this regard, according to this embodiment, the first gate electrode 431 is formed so as to partly overlap the second gate electrode 433, so that the interval between the first gate electrode 431 and the second gate electrode 433 becomes the thickness of the insulating film ILD and becomes narrower than the interval of the gate electrodes formed by the above method. Therefore, even when the voltages which are applied to the respective gate electrodes 431 and 433 are low, the channel layers which are formed by both the gate electrodes 431 and 433 are connected, and hence, the increases in the threshold voltage and the on-resistance can be suppressed.

Incidentally, the sixth embodiment can also be performed through an appropriate alteration in, for example, an aspect stated below.

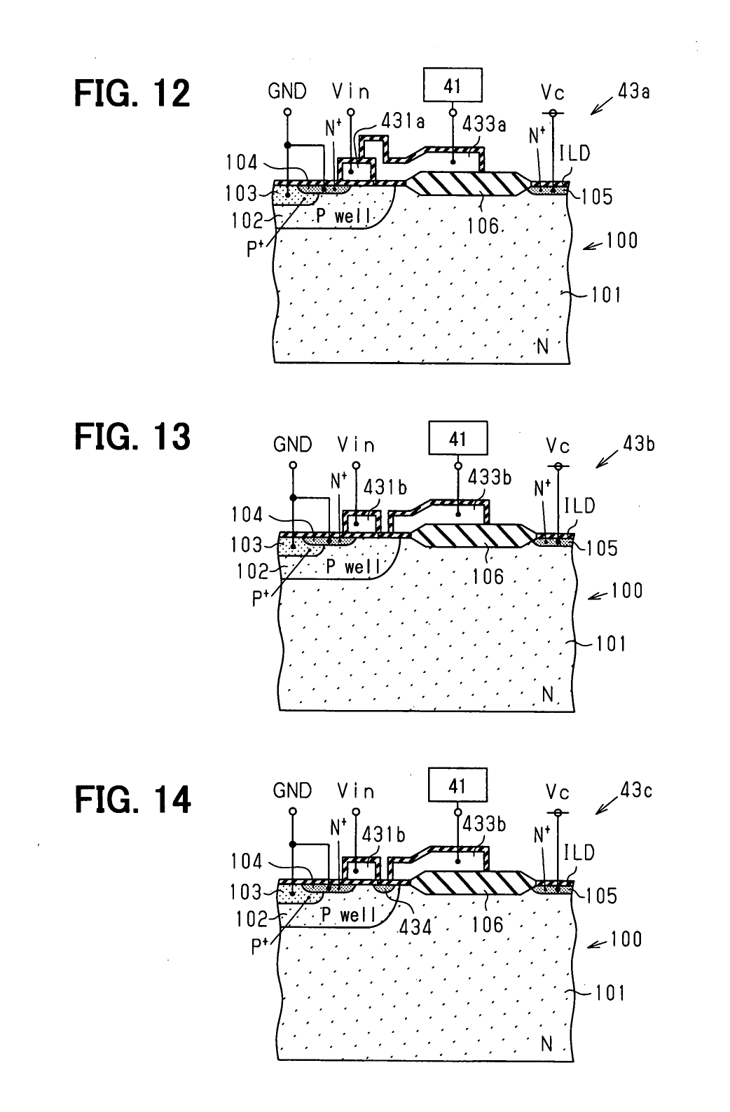

In the sixth embodiment, each first gate electrode 431 has been formed so as to partly overlap the corresponding second gate electrode 433. As shown in FIG. 12, however, each second gate electrode 433b may well be formed so as to partly overlap a corresponding first gate electrode 431a. Also in this way, advantages equivalent to those of the foregoing sixth embodiment, that is, the fourth embodiment are attained, and increases in the threshold voltage and on-resistance of each transistor 43a can be suppressed.

In the sixth embodiment, the first gate electrode 431 and the second gate electrode 433 have been formed so as to partly overlap one over the other. As shown in FIG. 13, however, if the first gate electrode 431b and second gate electrode 433b of each transistor 43b can be formed at a sufficiently short distance, both the gate electrodes 431b and 433b may well be formed so as not to overlap. According to this aspect, the gate electrodes 431b and 433b can be formed at one layer, in other words, at the same time, so that the number of processing steps can be decreased to simplify a process.

Further, in addition to the configuration of FIG. 13, a diffusion layer 434 of N-type may well be formed in the P well 102 in correspondence with the gap between the first gate electrode 431b and the second gate electrode 433b, as shown in FIG. 14.

The impurity concentration of the diffusion layer 434 is made the same as the concentration (N⁺) of the source region 104 by way of example. With such a configuration, even when the first gate electrode 431b and the second gate electrode 433b are not formed at the sufficiently short distance, channel layers which are respectively formed by the first and second gate electrodes 431b and 433b are connected by the diffusion layer 434, so that each transistor 43c can be turned on by low gate voltages, and increases in the threshold voltage and on-resistance of the transistor can be suppressed.

In each of the sixth embodiment and the modifications, the first gate electrode 431 or the like has been connected to the operating voltage input terminal Vin, and the second gate electrode 433 or the like has been connected to the memory region 41. It is also allowed, however, that the first gate electrode 431 or the like is connected to the memory region 41, and that the second gate electrode 433 or the like is connected to the operating voltage input terminal Vin. Besides, they may well be connected to the power source circuit (voltage control circuit) which is formed on the substrate formed with these transistors, in the same manner as in the fifth embodiment. It is to be understood that advantages equivalent to those of the sixth embodiment are attained even with these configurations.

### Seventh Embodiment

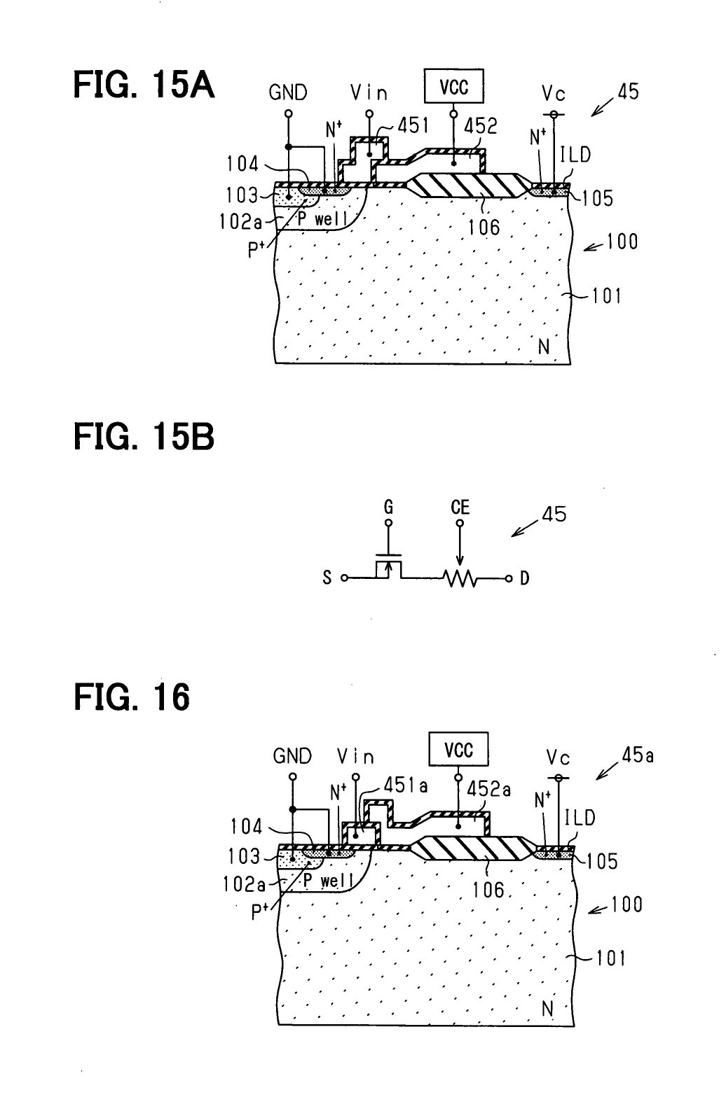

Next, a seventh embodiment of a semiconductor device according to this invention will be described with reference to FIGS. 15A and 15B.

FIG. 15A schematically shows an example of the side sectional structure of a transistor 45 which is formed in the semiconductor device of this embodiment. The transistor 45 is applied to the transistors L11-L15, L21-L25, L31-L35, and L41-L45 which constitute the LDMOS regions 10-40 in the first to fourth embodiments.

As shown in FIG. 15A, the transistor 45 basically includes on a semiconductor substrate 100, a gate electrode 451 being a first control electrode which is connected to an operating voltage input terminal Vin by a suitable wiring, and a control electrode 452 being a second control electrode which is formed in adjacency to the gate electrode 451 and which is connected to a voltage control circuit (not shown) by a suitable wiring. That is, the transistor 45 of this embodiment is such that a gate electrode which is formed extending from a source region 104 to a field oxide film 106 is divided into the gate electrode 451 and the control electrode 452. In addition, the gate electrode 451 is formed so as to partly overlap the control electrode 452.

In addition, a channel region 102a is formed in such a manner that the length thereof in the direction of the path of current, between the source region 104 and a drain region 101 (a drain contact portion 105) is shorter than in the sixth embodiment. Besides, the gate electrode 451 is formed so as to cover a region which extends from the source region 104 to the drain region 101, and the control electrode 452 is formed so as to cover the upper part of the drain region 101.

Next, the operation of the transistor 45 thus configured will be described.

The gate electrode 451 covering the channel region 102a forms a channel layer (inversion layer) in the channel region 102a, on the basis of a predetermined operating voltage applied from the operating voltage input terminal Vin. Incidentally, the channel layer thus formed connects the source region 104 and the drain region 101 electrically. Accordingly, the gate electrode 451 which is formed so as to cover the channel region 102a constitutes a MOS transistor of N-type, together with the source region 104 and the drain region 101. The MOS transistor is turned on/off by the predetermined operating voltage which is applied from the operating voltage input terminal Vin to the gate electrode 451.

The control electrode 452 which covers the upper part of the drain region 101 opposes to this drain region through an insulating film ILD, and functions as a capacitor. Therefore, when a plus voltage is applied to the control electrode 452, a charge accumulation layer in which electrons are accumulated is formed in the drain region 101 opposing to the control electrode 452.

The drain region 101 is usually set at a low impurity concentration in order to ensure a withstand voltage, and it has a high resistance, so that the current chiefly flows through the charge accumulation layer. The quantity of the electrons which are accumulated in the charge accumulation layer corresponds to the voltage applied to the control electrode 452, and further, the current which corresponds to the quantity of the accumulated electrons flows. Therefore, the easiness of the flow of the current, namely, a resistance value can be controlled by the voltage which is applied to the control electrode 452. In addition, the resistance value of the charge accumulation layer acts at the time of the turn-on of the MOS transistor which is controlled by the gate electrode 451. That is, the transistor 45 functions as the MOS transistor, and a variable resistor connected in series with this transistor, as shown in FIG. 15B. Besides, the on-resistance of the transistor 45 can be changed by the voltage which is applied to the control electrode 452. Therefore, the on-resistance value can be precisely controlled by adopting the transistor 45 in this embodiment, more than in an example in which a plurality of MOS transistors are connected in parallel and in which an on-resistance value is adjusted in accordance with the numbers of the transistors under on/off-states.

Incidentally, a potential applied to the source region 104 (the ground (GND) potential in FIG. 15A) and a plus constant potential can be adopted as potentials which are applied to the control electrode 452. With the source potential and the ground potential, the charge accumulation layer is not formed, so that a large resistance value (high resistance) is exhibited, and in the case of applying the plus voltage, the charge accumulation layer is formed, and a small resistance value (low resistance) is exhibited.

As described above, in accordance with the semiconductor device according to the seventh embodiment, advantages to be listed below are obtained.

(1) In the transistor 45, the gate electrode which is formed so as to extend from the source region 104 to the field oxide film 106 has been divided into the gate electrode 451 which covers the region extending from the source region 104 to the drain region 101, and the control electrode 452 which covers the upper part of the drain region 101. This transistor becomes equivalent to the structure in which the MOS transistor and the variable resistor are connected in series. Accordingly, the predetermined operating voltage applied from the operating voltage input terminal Vin is applied to the gate electrode 451, and the predetermined voltage is applied to the control electrode 452, whereby the on-resistance value between the source region 104 and the drain contact portion 105 can be precisely controlled.

(2) Since the control electrode 452 is not directly pertinent to the on/off operations of the transistor 45, this transistor 45 is turned-on/off substantially by the voltage applied to the gate electrode 451. In addition, since the opposing area between the first gate electrode 451 and the drain region becomes smaller than in the transistor of the prior-art example, and hence, a parasitic capacitance can be made smaller.

(3) The gate electrode 451 has been formed so as to partly overlap the control electrode 452. In the same manner as in the sixth embodiment, accordingly, increase in the on-resistance of the transistor 45 can be suppressed. More specifically, the gate electrode 451 and the control electrode 452 need to be electrically separated (brought into an open state). Therefore, when the gate electrode 451 and the control electrode 452 are excessively spaced, a part of high resistance is formed between the channel layer formed by the gate electrode 451 and the charge accumulation layer formed by the control electrode 452, and the on-resistance value which is controlled by the control electrode 452 becomes difficult of contributing to the operation of the transistor 45, so that the increase of the on-resistance is incurred.

In this regard, according to this embodiment, the gate electrode 451 is formed so as to partly overlap the control electrode 452, so that the interval between the gate electrode 451 and the control electrode 452 becomes the thickness of the insulating film ILD and becomes narrower than the interval of the electrodes formed by etching or the like expedient. Therefore, the part of the high resistance is not formed, or it becomes small, so that the increase of the on-resistance can be suppressed.

Incidentally, the seventh embodiment can also be performed through an appropriate alteration in, for example, an aspect stated below.

In the seventh embodiment, the gate electrode 451 has been formed so as to partly overlap the control electrode 452. As shown in FIG. 16, however, a control electrode 452a may well be formed so as to partly overlap a gate electrode 451a. Also in this way, advantages equivalent to those of the foregoing seventh embodiment are attained, and increase in the on-resistance of a transistor 45a can be suppressed.

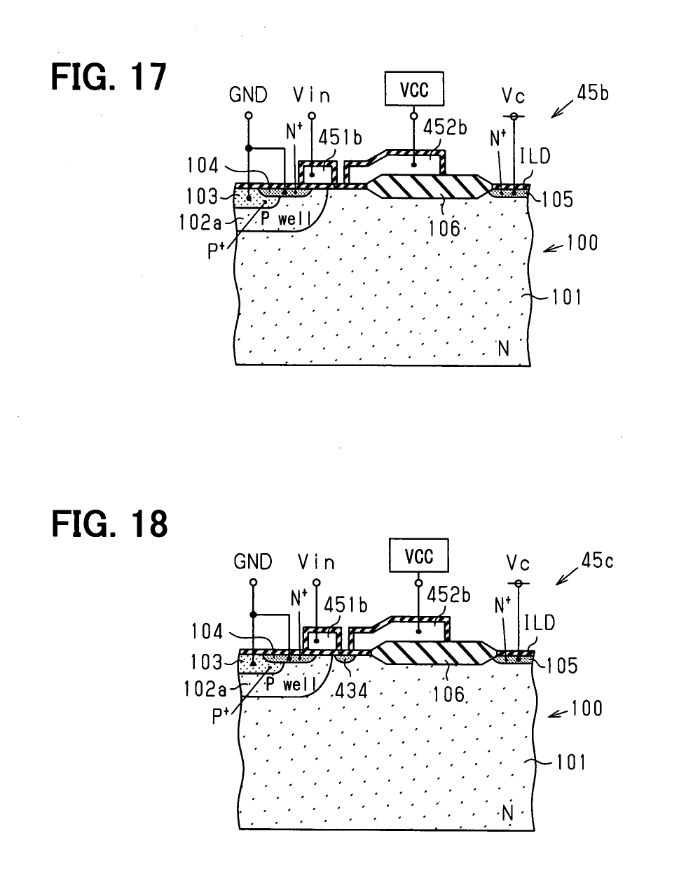

In the seventh embodiment, the gate electrode 451 and the control electrode 452 have been formed so as to partly overlap one over the other. As shown in FIG. 17, however, if the gate electrode 451b and control electrode 452b of a transistor 45b can be formed at a sufficiently short distance, they may well be formed so as not to overlap. According to this aspect, the gate electrode 451b and the control electrode 452b can be formed at one layer, in other words, at the same time, so that the number of processing steps can be decreased to simplify a process.

Further, in addition to the configuration of FIG. 17, a diffusion layer 434 of N-type may well be formed in the P well 102 in correspondence with the gap between the gate electrode 451b and the control electrode 452b, as shown in FIG. 18. The impurity concentration of the diffusion layer 434 is made the same as the concentration (N⁺) of the source region 104 by way of example. With such a configuration, even when the gate electrode 451b and the control electrode 452b are not formed at the sufficiently short distance, a channel layer which is formed by the gate electrodes 451, and a charge accumulation layer which is formed by the control electrode 452 are connected by the diffusion layer 434, so that increase in the on-resistance of the transistor can be suppressed.

Incidentally, the foregoing embodiments can also be performed through appropriate alterations in, for example, aspects stated below.

In each of the third to seventh embodiments, the drain electrodes D of the transistors L31-L35 or L41-L45 have been formed in a manner to be electrically separated, and the source electrodes S of the transistors L31-L35 or L41-L45 have been formed in a manner to be electrically connected through the diffusion layer S (N) formed within the semiconductor substrate C3 or C4. To the contrary, it is also allowed that the source electrodes S of the transistors L31-L35 or L41-L45 are formed in a manner to be electrically separated, and that the drain electrodes D of the transistors L31-L35 or L41-L45 are formed in a manner to be electrically connected through the diffusion layer Dc (N⁺) formed within the semiconductor substrate C3 or C4. In short, the advantage (3) of the foregoing third embodiment can be attained if the individual gate electrodes G are formed as the single electrode, whereupon either electrodes of the drain electrodes D and the source electrodes S are formed in the manner to be electrically separated, and the other electrodes are formed in the manner to be electrically connected through the diffusion layer formed within the semiconductor substrate.

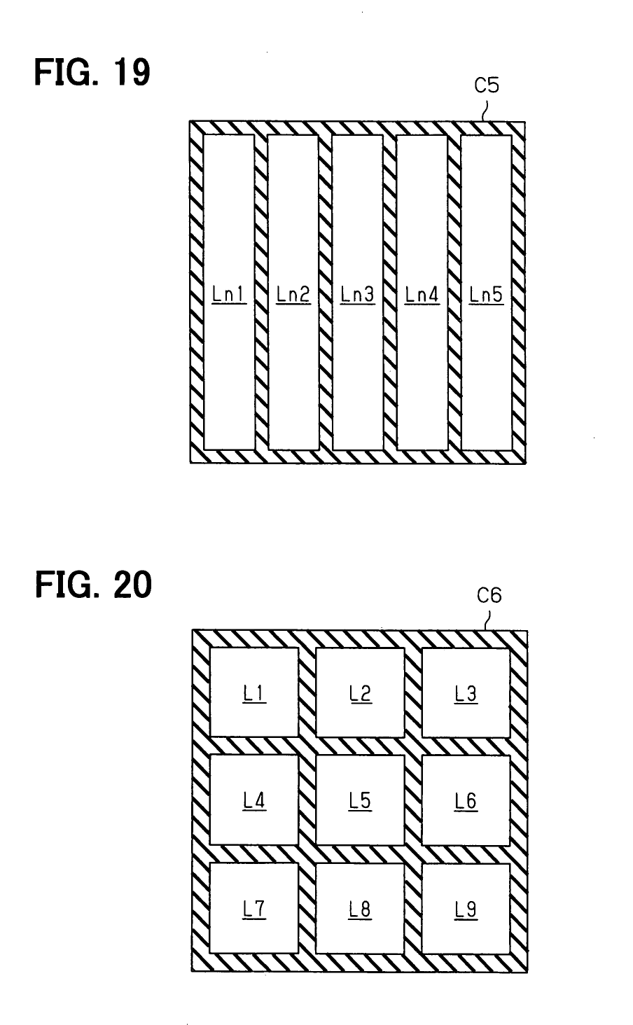

Besides, it is also allowed that such transistors Ln1-Ln5 are respectively isolated in an array manner as shown in FIG. 19 by way of example, whereupon they are arrayed and formed on a semiconductor substrate C5, and that gate electrodes constituting the transistors Ln1-Ln5, and either electrodes of similar drain electrodes and source electrodes are electrically connected by wirings, respectively. Alternatively, it is also allowed that transistors L1-L9 are respectively isolated in a matrix manner as shown in FIG. 20 by way of example, whereupon they are arrayed and formed on a semiconductor substrate C6, and that gate electrodes constituting the transistors L1-L9, and either electrodes of similar drain electrodes and source electrodes are electrically connected by wirings, respectively. Such a structure is complicated and therefore increases the manufacturing man-hour, but it becomes a desirable structure for the purpose of stabilizing the respective characteristics of the plurality of divided transistors. Further, in this case, the degree of freedom concerning the array of the plurality of transistors is heightened.

In each of the third to seventh embodiments, the nonvolatile memory region 31 has been formed in the semiconductor substrate C3 formed with the LDMOS region 30, or the nonvolatile memory region 41 has been formed in the semiconductor substrate C4 formed with the LDMOS region 40 and the N-channel MOS region 42, but this configuration is not restrictive. The memory cells M31-M35 constituting the nonvolatile memory region 31 may well be formed on a separate semiconductor substrate, and be respectively connected to the transistors L31-L35 constituting the LDMOS region 30 formed in the semiconductor substrate C3, by metallic wirings by way of example. Alternatively, the memory cells M41-M45 constituting the nonvolatile memory region 41, and the MOS transistors N41-N45 constituting the N-channel MOS region 42 may well be formed on a separate semiconductor substrate, and be respectively connected to the transistors L41-L45 constituting the LDMOS region 40 formed in the semiconductor substrate C4, by metallic wirings by way of example. In short, a concrete aspect for realization is as desired with any structure in which the equivalent circuit shown in FIG. 5 or FIG. 7 is realized, that is, with any structure in which the operating voltage is applied in common to the gate electrodes of the plurality of transistors connected in parallel with the path of the current, in which the operating information that indicates whether or not the current is to be fed to the plurality of transistors is variably set in the nonvolatile memory, and in which the transistors that have the current fed thereto are selectively activated on the basis of the information.

Besides, the first to seventh embodiments can also be performed through appropriate alterations in, for example, aspects stated below.

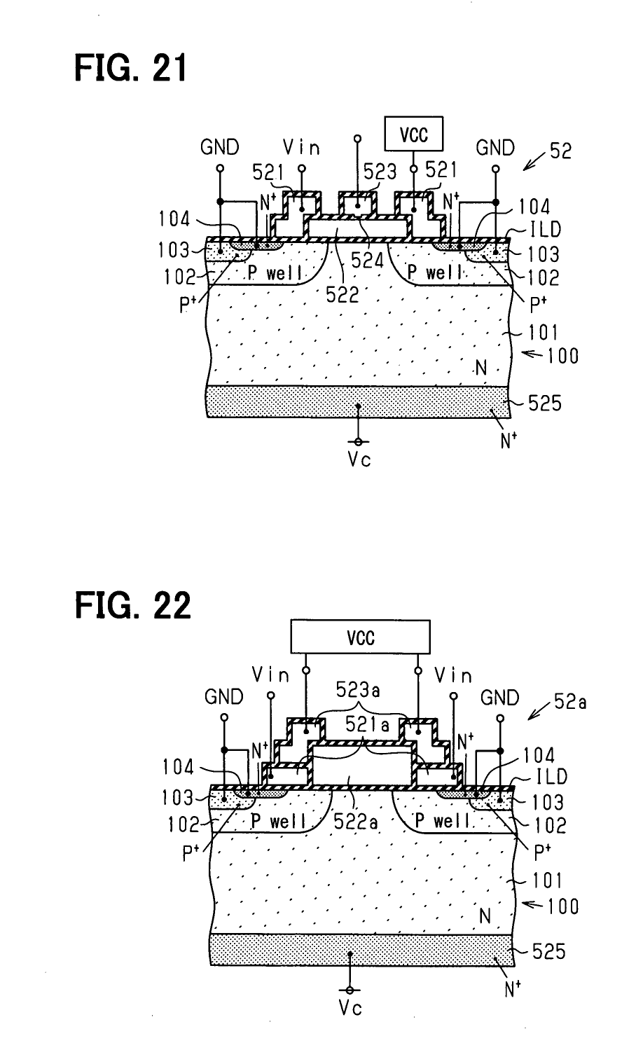

In each of the embodiments, the transistor having the LDMOS structure, the drain electrode D and the source electrode S of which are connected so as to intervene in the current path of the load to-be-operated Ld, has been adopted as the transistors which are arrayed and formed on the semiconductor substrate in a manner to be divided into the plurality of transistors connected in parallel, but this configuration is not restrictive. Otherwise, as shown in FIG. 21 as a figure corresponding to FIG. 9 illustrated before, it is also allowed to adopt each transistor 52 having a built-in memory, which includes a floating gate electrode 522 that is formed in adjacency to the corresponding one 521 of the gate electrodes of the plurality of transistors, a tunnel film 524 that is formed on the floating gate electrode 522, and a control gate electrode 523 that is stacked and formed on the tunnel film 524. In addition, the on/off of each bit is variably set on the basis of the exchange of electrons through the tunnel film 524 between the control gate electrode 523 and the floating gate electrode 522, the exchange corresponding to a potential applied to the control gate electrode 523. Alternatively, as shown in FIG. 22 as a figure corresponding to FIG. 10 illustrated before, it is also allowed that the control gate electrode 523a of each transistor 52a having a built-in memory is stacked and formed on a floating gate electrode 522a so as to cover the corner parts of the floating gate electrode 522a. In addition, the on/off of each bit of operating information is variably set by utilizing an electric field concentration at the corner part of the floating gate electrode 522a as corresponds to a potential applied to the control gate electrode 523a through the operation of a voltage control circuit. In short, the present invention can also be applied to the transistor which has a VDMOS (Vertical Diffused Metal Oxide Semiconductor) structure.

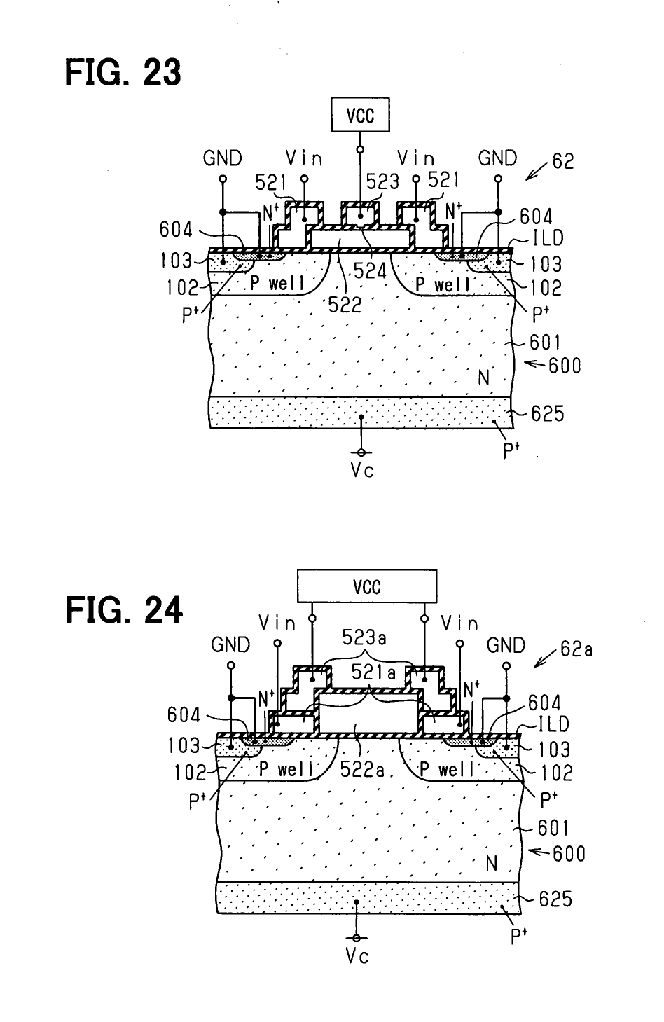

Further, the application scope of the present invention is not restricted to the transistors having the LDMOS structure and the VDMOS structure. Otherwise, by way of example, as shown in FIG. 23 as a figure corresponding to FIGS. 9 and 21 illustrated before, it is also allowed to form each transistor 62 having a built-in memory, which has a structure conforming to the foregoing transistor 52 having the built-in memory, on a semiconductor substrate 600 in which a base region 601 made of a diffusion layer of N-type constructs the greater part thereof. By the way, in such a structure, in the same manner as in the foregoing transistor 52 having the built-in memory, the on/off of each bit is variably set on the basis of the exchange of electrons through the tunnel film 524 between the control gate electrode 523 and the floating gate electrode 522, the exchange corresponding to a potential applied to the control gate electrode 523. In addition, in the transistor 62 having the built-in memory as has been brought into an on-state, current fed from a circuit power source Vc flows through a collector contact portion 625 which is made of a diffusion layer (P⁺) at a concentration higher than that of a channel region 102, the base region 601, the channel region 102, and an emitter region 604 which is made of a diffusion layer (N⁺) at a concentration higher than that of the base region 601, and it leads to the ground (GND). Otherwise, as shown in FIG. 24 as a figure corresponding to FIGS. 10 and 22 illustrated before, it is also allowed to form each transistor 62a having a built-in memory, which has a structure conforming to the foregoing transistor 52a having the built-in memory, on a semiconductor substrate 600 in which a base region 601 made of a diffusion layer of N-type constructs the greater part thereof. In such a structure, in the same manner as in the foregoing transistor 52a having the built-in memory, the control gate electrode 523a of the transistor 62a having the built-in memory is stacked and formed on a floating gate electrode 522a so as to cover the corner parts of the floating gate electrode 522a. In addition, the on/off of each bit of operating information is variably set by utilizing an electric field concentration at the corner parts of the floating gate electrode 522a as corresponds to a potential applied to the control gate electrode 523a through the operation of a voltage control circuit. By the way, in the transistor 62a having the built-in memory as has been brought into an on-state, current fed from a circuit power source Vc flows through a collector contact portion 625 which is made of a diffusion layer (P⁺) at a concentration higher than that of a channel region 102, the base region 601, the channel region 102, and an emitter region 604 which is made of a diffusion layer (N⁺) at a concentration higher than that of the base region 601, and it leads to the ground (GND). That is, the transistor having an IGBT (Insulated Gate Bipolar Transistor) structure, the collector electrode and emitter electrode of which are connected so as to intervene in the current path of a load to-be-operated, can be adopted as the transistors which are arrayed and formed on the semiconductor substrate in a manner to be divided into the plurality of transistors.

Although the transistors in each of the foregoing embodiments have been the MOS transistors of N-type, they may well be constructed of MOS transistors of P-type. It is also allowed to employ a semiconductor device of so-called “CMOS structure” in which conductive types are appropriately altered, that is, MOS transistors of N-type and MOS transistors of P-type are formed on an identical semiconductor substrate.

The transistors in each of the fifth to seventh embodiments and modifications are formed on an identical semiconductor substrate, together with other elements. In a case, for example, where the transistor 45 in the seventh embodiment is applied to the transistors L21-L25 (refer to FIG. 3) in the second embodiment, the memory cells M21-M25 constituting the nonvolatile memory region 21, and the MOS transistors N21-N25 constituting the N-channel MOS region 22 are formed on the identical semiconductor substrate, together with this transistor 45.

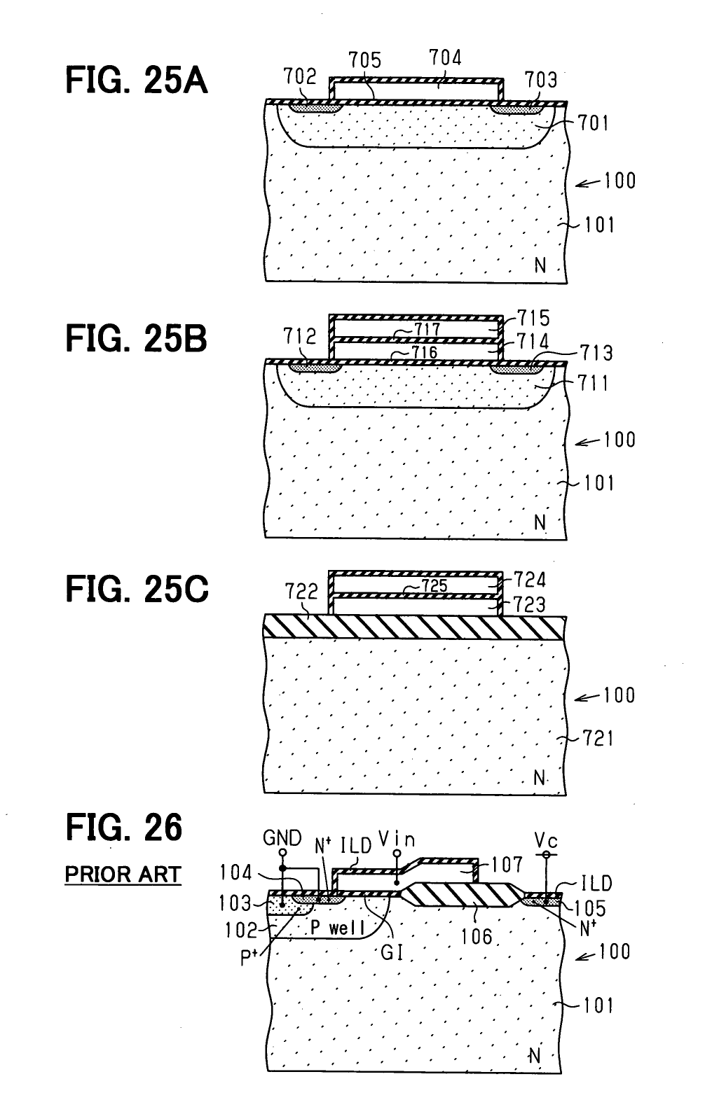

As shown in FIG. 25A by way of example, the MOS transistor is formed with a source region 702 and a drain region 703 of N-type in a well 701 of P-type, and it is formed with a gate electrode 704 so as to cover the part of the well 701 between the source region 702 and the drain region 703. In addition, the gate electrode 704 is insulated from the well 701, etc. by a gate oxide film 705. This MOS transistor is formed simultaneously with the gate electrodes, insulating films, source regions, etc. of the transistors in each of the foregoing embodiments.

As shown in FIG. 25B by way of example, the memory cell (nonvolatile memory) is formed with a source region 712 and a drain region 713 of N-type in a well 711 of P-type, and it is formed with a floating gate electrode 714 and a control gate electrode 715 so as to cover the part of the well 711 between the source region 712 and the drain region 713. In addition, the floating gate electrode 714 is insulated from the well 711, etc. by a tunnel oxide film 716, and a dielectric film 717 is interposed between the floating gate electrode 714 and the control gate electrode 715. This nonvolatile memory is formed simultaneously with the first gate electrodes, second gate electrodes (control electrodes in the seventh embodiment), insulating films, source regions, etc. of the transistors in each of the fifth to seventh embodiments.

Besides, a capacitor is formed on the identical semiconductor substrate as the other element. The capacitor is included in a voltage control circuit which feeds predetermined voltages to, for example, a second gate electrode. As shown in FIG. 25C, the capacitor is formed with a LOCOS oxide film 722 formed on the substrate (or a diffusion layer) 721, and it is formed with a lower electrode 723 and an upper electrode 724 on the LOCOS oxide film 722. A dielectric film 725 is interposed between the lower electrode 723 and the upper electrode 724. This capacitor is formed simultaneously with the first gate electrodes, second gate electrodes (control electrodes in the seventh embodiment), insulating films, source regions, etc. of the transistors in each of the fifth to seventh embodiments.

In this manner, the other element formed on the same semiconductor substrate as that of the transistors in each of the fifth to seventh embodiments is formed by an identical process (for example, the second gate electrode 433 shown in FIG. 11 and the floating gate electrode 714 shown in FIG. 25B or the lower electrode 723 shown in FIG. 25C), whereby the semiconductor device in each of the embodiments can be obtained with the increase of manufacturing steps suppressed.

In each of the foregoing embodiments, at least one of the plurality of transistors constituting any of the LDMOS regions 10-40 may well be replaced with the transistor shown in each of the fifth to seventh embodiments and modifications. Owing to this configuration, the plurality of transistors constituting each of the LDMOS regions 10-40 are subjected to a control for the floating gate or divided gate electrodes, or the control electrode, in addition to the control based on the memory region and the N-channel MOS region, whereby the transistors can be controlled more precisely.

In each of the fifth to seventh embodiments and modifications, a metallic wiring may well be arranged in superposition on the gate electrode or the control electrode. Since the gate electrode is made of, for example, polycrystal silicon, it is larger in the value of a parasitic resistance than the metallic wiring (aluminum, copper or the like). As in the third or fourth embodiment, the plurality of transistors L31-L35 or L41-L45 constituting the LDMOS region 30 or 40 have been electrically connected in parallel, and the gates of the individual transistors L31-L35 or L41-L45 have been connected to the operating voltage input terminal Vin in common. Since such gate electrodes are formed as the single common gate electrode G3 or G4 as shown in FIG. 6 or FIG. 8, a voltage drop sometimes arises due to the parasitic resistance. Therefore, the metal wiring is arranged in superposition on the gate electrode, and the metal wiring and the gate electrode are connected by contact holes formed at a plurality of parts, whereby a substantial wiring length is shortened to decrease the parasitic resistance. Thus, a voltage can be precisely applied to the gate electrode, and a more precise control can be performed. Incidentally, also in the case where the gate electrodes of the transistors are individually formed as in the first or second embodiment, the parasitic resistance of the gate electrode can be decreased by arranging the metallic wiring.

Still further, the application scope of the present invention is not restricted to transistors each having a built-in memory or transistors each having an LDMOS structure, VDMOS structure or IGBT structure. In short, it is allowed to employ any structure in which transistors each having a MOS structure that includes first and second electrodes connected so as to intervene in the path of current, and gate electrodes for controlling currents to flow between the first and second electrodes, in accordance with applied voltages, are arrayed on a semiconductor substrate in a manner to be divided into a plurality of transistors that are electrically connected in parallel with the path of the current. With such a structure, an effective channel width at the time when the plurality of divided transistors are regarded as a single transistor can be made variable within the semiconductor substrate, in accordance with the number of the transistors selectively activated on the basis of the operating information of the plurality of transistors variably set in a nonvolatile memory, and the intended object can be accomplished.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also with in the spirit and scope of the invention.

What is claimed is:

1. A semiconductor device comprising:
a semiconductor substrate;
a plurality of MOS type first transistors disposed on the semiconductor substrate; and
a nonvolatile memory for memorizing an operating information of each first transistor, wherein
the plurality of first transistors is electrically coupled in parallel with a current path,
each first transistor includes a first electrode and a second electrode disposed on the current path, and further includes a gate electrode for controlling current flowing between the first and second electrodes based on an applied voltage,
the operating information of each first transistor is variably set,
each first transistor is selectively set to an active state based on the operating information, and
when the plurality of first transistors provides a single transistor, an effective channel width of the single transistor is variable in accordance with the number of the first transistors under the active state.

2. The semiconductor device according to claim 1, wherein
the operating information shows whether an operating voltage is applied to the gate electrode of each first transistor or not, and
each first transistor is selectively set to the active state when the operating voltage is applied to the gate electrode based on the operating information.

3. The semiconductor device according to claim 2, wherein
the operating information has the number of bits, which is equal to the number of the plurality of first transistors,
the nonvolatile memory includes a plurality of switching elements capable of switching on and off in accordance with a logic level of each bit providing the operating information,
the plurality of switching elements is electrically coupled with each other in such a manner that each switching element is disposed in a line for applying the operating voltage to the gate electrode of each first transistor, and
a line connecting between each gate electrode and each switching element is grounded through a pull-down resistor, respectively, so that the first transistor corresponding to the switching element under an on-state is selectively set to the active state.

4. The semiconductor device according to claim 3, wherein
the nonvolatile memory and the plurality of first transistors are disposed in the same semiconductor substrate.

5. The semiconductor device according to claim 3, further comprising:
a plurality of MOS type second transistors, wherein
a source electrode and a drain electrode of each MOS type second transistor are disposed in a line for applying the operating voltage to the gate electrode of each first transistor, respectively,
the operating information has the number of bits, which is equal to the number of the plurality of first transistors,
the nonvolatile memory includes a plurality of switching elements capable of switching on and off in accordance with a logic level of each bit providing the operating information,
the plurality of switching elements is coupled with each other in parallel to a memory power source,
a gate electrode of each MOS type second transistor is coupled with the memory power source through each switching element,
a line connecting between the gate electrode of each first transistor and each second transistor is grounded through a first pull-down resistor, and
the gate electrode of each second transistor is grounded through a second pull-down resistor, respectively, so that the first transistor corresponding to the switching element under an on-state and the second transistor under an on-state is selectively set to the active state.

6. The semiconductor device according to claim 5, wherein
the nonvolatile memory, the plurality of second transistors and the plurality of first transistors are disposed in the same semiconductor substrate.

7. The semiconductor device according to claim 2, wherein
the first electrodes of the plurality of first transistors are electrically coupled with each other through a diffusion layer disposed in the semiconductor substrate,
the second electrodes of the plurality of first transistors are electrically coupled with each other through another diffusion layer disposed in the semiconductor substrate, and
the gate electrodes of the plurality of first transistors are electrically separated from each other.

8. The semiconductor device according to claim 2, wherein
the plurality of first transistors is arranged in the semiconductor substrate in an array manner or in a matrix manner so as to separate from each other,
the first electrode of each first transistor is electrically coupled with each other through a wiring, and
the second electrode of each first transistor is electrically coupled with each other through another wiring.

9. The semiconductor device according to claim 1, wherein
the operating voltage is commonly applied to the gate electrode of each first transistor,
the operating information shows whether current is supplied to each first transistor or not, and
the current is supplied to each first transistor based on the operating information so that the first transistor is selectively set to the active state.

10. The semiconductor device according to claim 9, wherein
the operating information has the number of bits, which is equal to the number of the plurality of first transistors,
the nonvolatile memory includes a plurality of switching elements capable of switching on and off in accordance with a logic level of each bit providing the operating information, and
the plurality of switching elements is electrically coupled with each other in such a manner that each switching element is disposed in a line for supplying the current to each first transistor so that the first transistor corresponding to the switching element under an on-state is selectively set to the active state.

11. The semiconductor device according to claim 10, wherein
the nonvolatile memory and the plurality of first transistors are disposed in the same semiconductor substrate.

12. The semiconductor device according to claim 11, wherein
the nonvolatile memory includes a floating gate, a tunneling film and a control gate,
the floating gate is arranged adjacent to the gate electrode of each first transistor,
the tunneling film is arranged on the floating gate,
the control gate is stacked on the tunneling film, and
the on/off state in each bit is variably set by giving and receiving electron between the floating gate and the control gate through the tunneling film in accordance with an electric potential applied to the control gate.

13. The semiconductor device according to claim 11, wherein
the nonvolatile memory includes a floating gate, a tunneling film and a control gate,
the floating gate is arranged adjacent to the gate electrode of each first transistor,
the control gate is stacked on the tunneling film to cover a corner of the floating gate, and
an on/off state in each bit is variably set by concentrating electric field at the corner of the floating gate in accordance with an electric potential applied to the control gate.

14. The semiconductor device according to claim 9, further comprising:
a plurality of MOS type second transistors, wherein
a source electrode and a drain electrode of each MOS type second transistor are disposed in a line for supplying current, respectively,
the operating information has the number of bits, which is equal to the number of the plurality of first transistors,
the nonvolatile memory includes a plurality of switching elements capable of switching on and off in accordance with a logic level of each bit providing the operating information,
the plurality of switching elements is coupled with each other in parallel to a memory power source,
a gate electrode of each MOS type second transistor is coupled with the memory power source through each switching element,
the gate electrode of each second transistor is grounded through a pull-down resistor, respectively, so that the first transistor corresponding to the switching element under an on-state and the second transistor under an on-state is selectively set to the active state.

15. The semiconductor device according to claim 14, wherein
the nonvolatile memory, the plurality of first transistors and the plurality of second transistors are disposed in the same semiconductor substrate.

16. The semiconductor device according to claim 15, wherein
each second transistor includes a gate electrode arranged adjacent to the gate electrode of the first transistor, and
the first transistor and the second transistor commonly include a channel region.

17. The semiconductor device according to claim 9, wherein
the gate electrode of each first transistor is provided by a single electrode corresponding to all channels of the plurality of first transistors,
one of the first electrodes and the second electrodes of the plurality of first transistors are electrically coupled with each other through a diffusion layer disposed in the semiconductor substrate, and
the other one of the first electrodes and the second electrodes of the plurality of first transistors are electrically separated from each other.

18. The semiconductor device according to claim 9, wherein
the plurality of first transistors is arranged in the semiconductor substrate in an array manner or in a matrix manner so as to separate from each other,
one of the gate electrodes, the first electrodes and the second electrodes of the plurality of first transistors are electrically coupled with each other through a wiring.

19. The semiconductor device according to claim 1, wherein
the first electrode of each first transistor provides a drain electrode,
the second electrode of each first transistor provides a source electrode, and
the drain electrode and the source electrode of each first transistor are coupled and arranged in a current line of a driving load to provide a LDMOS structure.

20. The semiconductor device according to claim 1, wherein
the first electrode of each first transistor provides a drain electrode,
the second electrode of each first transistor provides a source electrode, and
the drain electrode and the source electrode of each first transistor are coupled and arranged in a current line of a driving load to provide a VDMOS structure.

21. The semiconductor device according to claim 1, wherein
the first electrode of each first transistor provides a collector electrode,
the second electrode of each first transistor provides an emitter electrode, and
the collector electrode and the emitter electrode of each first transistor are coupled and arranged in a current line of a driving load to provide a IGBT structure.

22. A semiconductor device comprising:
a plurality of MOS type first transistors, wherein
the plurality of first transistors is electrically coupled in parallel with a current path,
each first transistor includes a first electrode and a second electrode disposed on the current path, and further includes a gate electrode for controlling current flowing between the first and second electrodes based on an applied voltage,
the gate electrode of at least one of first transistors includes a first gate electrode and a second gate electrode,
the first gate electrode is disposed on the first electrode and covers a channel region, and
the second gate electrode is disposed on the channel region and covers the second electrode.

23. The semiconductor device according to claim 22, wherein
the first gate electrode is overlapped with at least a part of the second gate electrode.

24. The semiconductor device according to claim 22, wherein
the first gate electrode and the second gate electrode are not overlapped with each other.

25. The semiconductor device according to claim 24, further comprising:
a region having a conductive type different from the channel region, the region which is arranged between the first gate electrode and the second gate electrode.

26. The semiconductor device according to claim 22, wherein
an electric potential of the first gate electrode is constant and different from an electric potential of the second gate electrode.

27. The semiconductor device according to claim 26, further comprising:
a voltage control circuit disposed on the semiconductor substrate, wherein
the constant electric potential is supplied from the voltage control circuit.

28. The semiconductor device according to claim 22, further comprising:
a metallic wiring overlapped with the first gate electrode or the second gate electrode.

29. The semiconductor device according to claim 22, wherein
at least two of the plurality of first transistors include a first gate electrode and a second gate electrode, respectively,
one of the first electrodes and the second electrodes of the two of the plurality of first transistors are provided by a single electrode corresponding to all channel regions in the two of the plurality of first transistors,
one of the first electrodes and the second electrodes of the two of the plurality of first transistors are electrically coupled with each other through a diffusion layer disposed in the semiconductor substrate, and
the other one of the first electrodes and the second electrodes of the two of the plurality of first transistors are electrically separated from each other.

30. The semiconductor device according to claim 22, wherein
the plurality of first transistors is arranged in the semiconductor substrate in an array manner or in a matrix manner so as to separate from each other,
one of the first gate electrodes, the first electrodes and the second electrodes of the plurality of first transistors are electrically coupled with each other through a wiring.

31. The semiconductor device according to claim 22, wherein
the plurality of first transistors is arranged in the semiconductor substrate in an array manner or in a matrix manner so as to separate from each other,
the first gate electrode of each first transistor is electrically coupled with the first electrode and the second electrode through wirings, respectively.

32. The semiconductor device according to claim 22, wherein
the first electrode of each first transistor provides a drain electrode,
the second electrode of each first transistor provides a source electrode, and
the drain electrode and the source electrode of each first transistor are coupled and arranged in a current line of a driving load to provide a LDMOS structure.

33. The semiconductor device according to claim 22, wherein
the first electrode of each first transistor provides a drain electrode,
the second electrode of each first transistor provides a source electrode, and
the drain electrode and the source electrode of each first transistor are coupled and arranged in a current line of a driving load to provide a VDMOS structure.

34. The semiconductor device according to claim 22, wherein
the first electrode of each first transistor provides a collector electrode,
the second electrode of each first transistor provides an emitter electrode, and
the collector electrode and the emitter electrode of each first transistor are coupled and arranged in a current line of a driving load to provide a IGBT structure.

35. A semiconductor device comprising:
a plurality of MOS type first transistors, wherein
the plurality of first transistors is electrically coupled in parallel with a current path,
each first transistor includes a first electrode and a second electrode disposed on the current path, and further includes a gate electrode for controlling current flowing between the first and second electrodes based on an applied voltage,
the gate electrode of at least one of first transistors includes a first control electrode and a second control electrode,
the first control electrode covers a channel region disposed from the first electrode to the second electrode,
the first control electrode opens and closes between the first electrode and the second electrode, and
the second control electrode covers the second electrode.

36. The semiconductor device according to claim 35, wherein
the first control electrode is overlapped with at least a part of the second control electrode.

37. The semiconductor device according to claim 35, wherein
the second control electrode is overlapped on at least a part of the first control electrode.

38. The semiconductor device according to claim 35, wherein
the first control electrode and the second control electrode are not overlapped with each other.

39. The semiconductor device according to claim 38, further comprising:
a region having a conductive type different from the channel region, the region which is arranged between the first control electrode and the second control electrode.

40. The semiconductor device according to claim 35, wherein
an electric potential of the second control electrode is constant and different from an electric potential of the first control electrode.

41. The semiconductor device according to claim 40, wherein
the second control electrode has the electric potential to accumulate an electric charge on a surface of the second electrode.

42. The semiconductor device according to claim 40, further comprising:
a voltage control circuit disposed on the semiconductor substrate, wherein
the constant electric potential is supplied from the voltage control circuit.

43. The semiconductor device according to claim 40, wherein
the electric potential of the second control electrode is equal to the electric potential of the first electrode.

44. The semiconductor device according to claim 35, further comprising:
a metallic wiring overlapped with the first gate electrode or the second gate electrode.

45. The semiconductor device according to claim 35, wherein
at least two of the plurality of first transistors include a first control electrode and a second control electrode, respectively,
the first control electrodes of the two of the plurality of first transistors are provided by a single electrode corresponding to all channel regions in the two of the plurality of first transistors,
one of the first electrodes and the second electrodes of the two of the plurality of first transistors are electrically coupled with each other through a diffusion layer disposed in the semiconductor substrate, and
the other one of the first electrodes and the second electrodes of the two of the plurality of first transistors are electrically separated from each other.

46. The semiconductor device according to claim 35, wherein
the plurality of first transistors is arranged in the semiconductor substrate in an array manner or in a matrix manner so as to separate from each other,
the first control electrode is electrically coupled with one of the first electrode and the second electrode through a wiring.

47. The semiconductor device according to claim 35, wherein
the first electrode of each first transistor provides a drain electrode,
the second electrode of each first transistor provides a source electrode, and
the drain electrode and the source electrode of each first transistor are coupled and arranged in a current line of a driving load to provide a LDMOS structure.

48. The semiconductor device according to claim 35, wherein
the first electrode of each first transistor provides a drain electrode,
the second electrode of each first transistor provides a source electrode, and
the drain electrode and the source electrode of each first transistor are coupled and arranged in a current line of a driving load to provide a VDMOS structure.

49. The semiconductor device according to claim 35, wherein
the first electrode of each first transistor provides a collector electrode,
the second electrode of each first transistor provides an emitter electrode, and
the collector electrode and the emitter electrode of each first transistor are coupled and arranged in a current line of a driving load to provide a IGBT structure.
